(19) United States
(12) Patent Application Publication
(10) Pub. No.: US 2025/0351336 A1
(43) Pub. Date: Nov. 13, 2025

(54) SEMICONDUCTOR DEVICE

(71) Applicant: Samsung Electronics Co., Ltd., Suwon-si (KR)

(72) Inventors: Taegyu Kang, Suwon-si (KR); Jinwoo Han, Suwon-si (KR)

(21) Appl. No.: 18/958,019

(22) Filed: Nov. 25, 2024

(30) Foreign Application Priority Data
May 13, 2024 (KR) 10-2024-0062743

(51) Int. Cl. H10B 12/00

(52) U.S. Cl. CPC H10B 12/482; H10B 12/315; H10B 12/488

(57) ABSTRACT

A semiconductor device includes a bit line, a data storage structure spaced apart from the bit line, a word line between the bit line and the data storage structure, a dielectric pattern between the word line and the bit line, and a channel pattern that extends between the bit line and the data storage structure to each other. The channel pattern includes a channel region having the word line thereon, a first impurity region of a first conductivity type and a second impurity region of a second conductivity type different from the first conductivity type. The first and second impurity regions are between the channel region and the bit line. A distance between the first impurity region and the dielectric pattern is greater than a distance between the second impurity region and the dielectric pattern.

### CROSS-REFERENCE TO RELATED APPLICATION

This U.S. nonprovisional application claims priority under 35 U.S.C. § 119 to Korean Patent Application No. 10-2024-0062743 filed on May 13, 2024, in the Korean Intellectual Property Office, the disclosure of which is hereby incorporated by reference in its entirety.

### FIELD

The present inventive concepts relate to a semiconductor device, and more particularly, to a semiconductor device including a channel pattern.

### BACKGROUND

A semiconductor device may be an essential element in electronic industry due to properties such as compactness, multi-functionality, and/or low manufacturing cost. Semiconductor devices may encompass semiconductor memory devices storing logic data, semiconductor logic devices processing operations of logic data, and hybrid semiconductor devices having both memory and logic elements.

Demand for high speed and low consumption of electronic products may require that semiconductor devices embedded in the electronic products should have high operating speed and/or lower operating voltage. However, an increase in integration of semiconductor devices may cause a reduction in electrical properties and production yield of semiconductor devices. Therefore, research has been conducted to increase electrical properties and production yield of semiconductor devices.

### SUMMARY

Some embodiments of the present inventive concepts provide a semiconductor device with improved electrical properties and increased integration.

According to some embodiments of the present inventive concepts, a semiconductor device may comprise: a bit line; a data storage structure; a word line between the bit line and the data storage structure; a dielectric pattern between the word line and the bit line; and a channel pattern that extends between the bit line and the data storage structure. The channel pattern may include: a channel region having the word line thereon; a first impurity region of a first conductivity type; and a second impurity region of a second conductivity type different from the first conductivity type. The first and second impurity regions may be between the channel region and the bit line. A distance between the first impurity region and the dielectric pattern may be greater than a distance between the second impurity region and the dielectric pattern.

According to some embodiments of the present inventive concepts, a semiconductor device may comprise: a bit line; a data storage structure; a word line between the bit line and the data storage structure; and a channel pattern that extends between the bit line and the data storage structure. The channel pattern may include: a first impurity region of a first conductivity type; and a second impurity region of a second conductivity type different from the first conductivity type. The first and second impurity regions may be in contact with the bit line.

According to some embodiments of the present inventive concepts, a semiconductor device may comprise: a bit line; a data storage structure; a word line between the bit line and the data storage structure; and a channel pattern that extends between the bit line and the data storage structure. The channel pattern may include: a channel region having the word line thereon; a first source/drain region between the channel region and the bit line; and a second source/drain region between the channel region and the data storage structure. The first source/drain region may include: a first impurity region of a first conductivity type; and a second impurity region of a second conductivity type different from the first conductivity type. The first impurity region may include a first impurity of the first conductivity type. The second impurity region may include the first impurity of the first conductivity type and a second impurity of the second conductivity type. A concentration of the second impurity in the second impurity region may be greater than a concentration of the first impurity in the second impurity region.

### BRIEF DESCRIPTION OF THE DRAWINGS

FIG. 1A illustrates a simplified circuit diagram showing a semiconductor device according to some embodiments.

FIGS. 1B, 1C, and 1D illustrate simplified perspective views showing a semiconductor device according to some embodiments.

FIG. 2A illustrates a plan view showing a semiconductor device according to some embodiments.

FIG. 2B illustrates a cross-sectional view taken along line A-A′ of FIG. 2A.

FIG. 2C illustrates a cross-sectional view taken along line B-B′ of FIG. 2A.

FIG. 2D illustrates a cross-sectional view taken along line C-C′ of FIG. 2A.

FIG. 2E illustrates an enlarged view showing section E1 of FIG. 2A.

FIG. 2F illustrates an enlarged view showing section E2 of FIG. 2B.

FIG. 2G illustrates an enlarged view showing section E3 of FIG. 2D.

FIGS. 2H, 2I, and 2J illustrate energy band diagrams of a semiconductor device according to some embodiments.

FIGS. 3A, 3B, 3C, 4A, 4B, 4C, 5A, 5B, 5C, 6A, 6B, 6C, 6D, 7A, 7B, 7C, 7D, 7E, 7F, 8A, 8B, 8C, 9A, 9B, 9C, 9D, 9E, 10A, and 10B illustrate diagrams showing a method of fabricating a semiconductor device according to some embodiments.

FIG. 11A illustrates a perspective view showing a semiconductor device according to some embodiments.

FIG. 11B illustrates a cross-sectional view taken along line F-F′ of FIG. 11A.

FIG. 11C illustrates a cross-sectional view taken along line G-G′ of FIG. 11A.

FIG. 11D illustrates an enlarged view showing section E4 of FIG. 11C.

FIG. 12 illustrates a plan view showing a semiconductor device according to some embodiments.

### DETAILED DESCRIPTION OF EMBODIMENTS

The terms “first,” “second,” etc., may be used herein merely to distinguish one component, layer, direction, etc. from another. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly” on, or “in direct contact” or “directly connected,” no intervening components or layers are present.

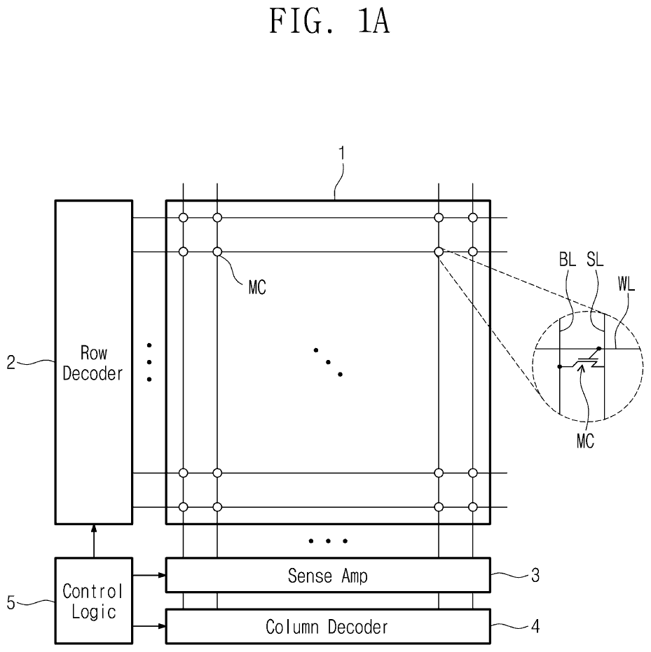

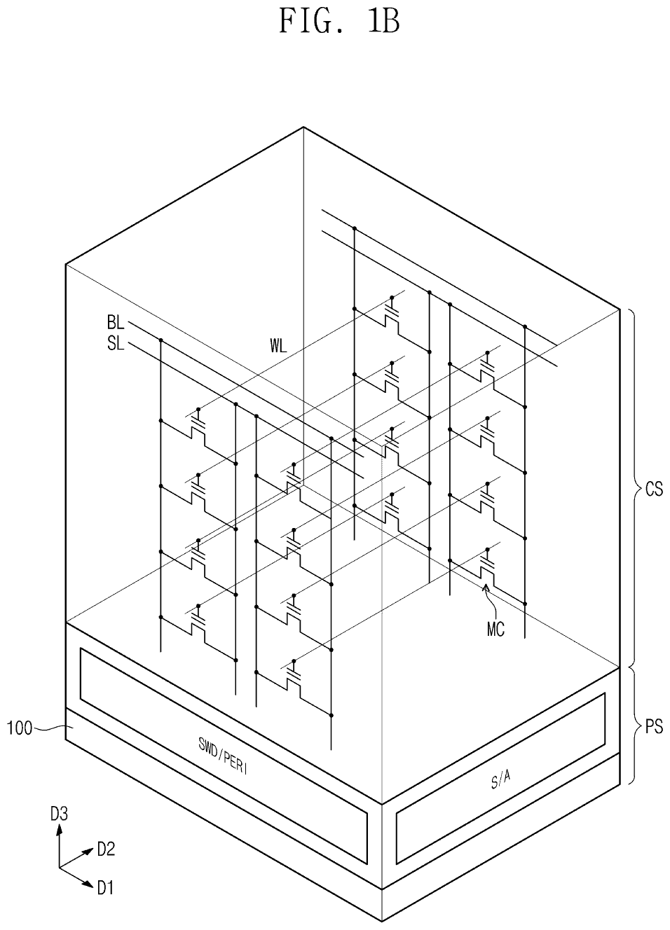

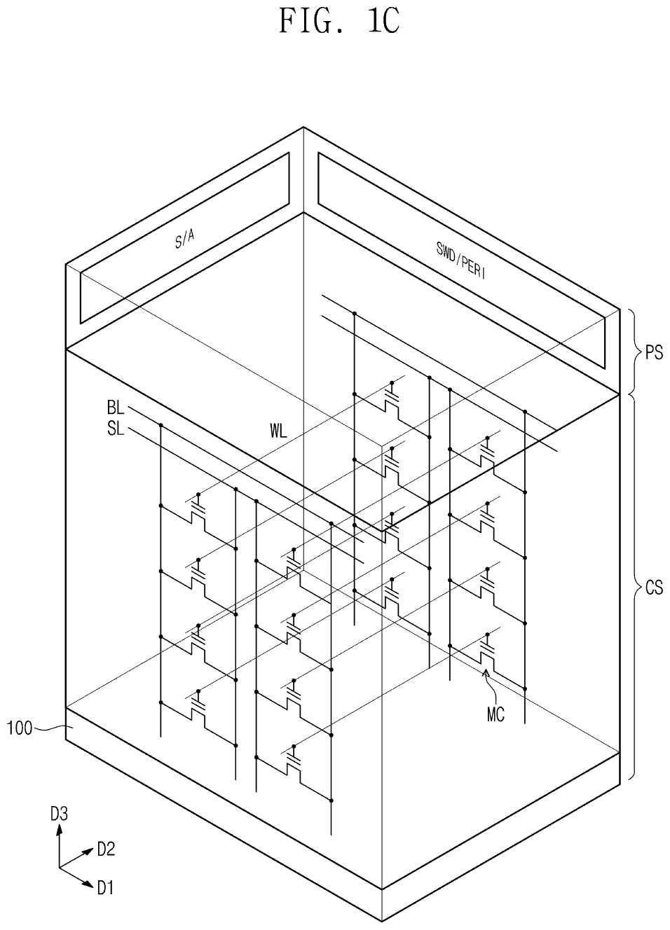

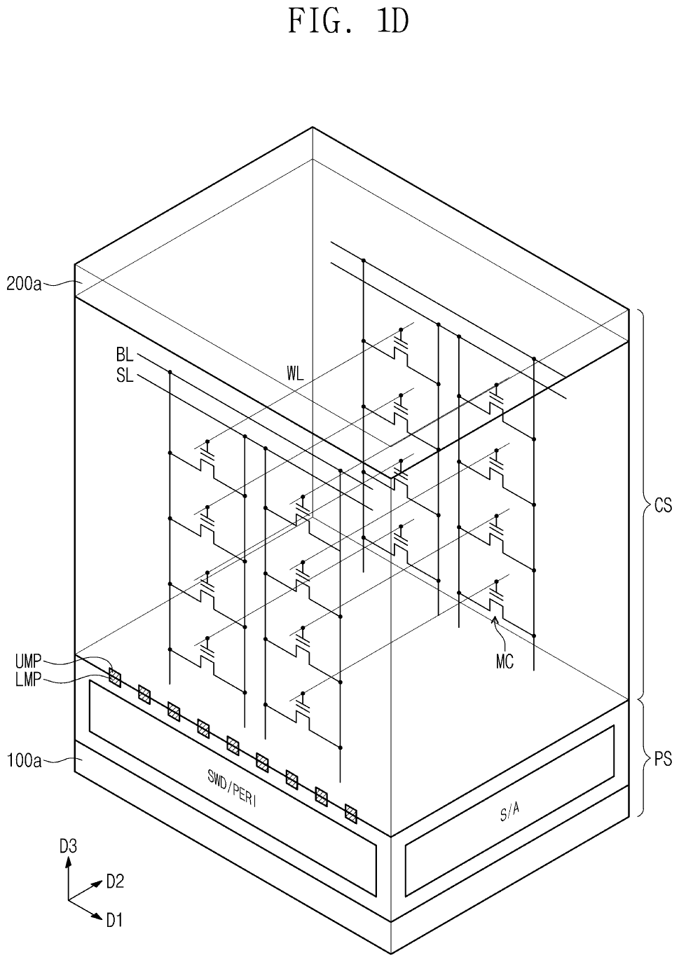

FIG. 1A illustrates a simplified circuit diagram showing a semiconductor device according to some embodiments.

Referring to FIG. 1A, a semiconductor device may include a memory cell array 1, a row decoder 2, a sense amplifier 3, a column decoder 4, and a control logic 5.

The memory cell array 1 may include word lines WL, bit lines BL, source lines SL, and memory cells MC. The memory cells MC may be three-dimensionally arranged, and the memory cell MC may be connected to one word line WL, one bit line BL, and one source line SL. In some embodiments, each of the memory cells MC may be formed of one transistor including a memory layer or a data storage layer.

The row decoder 2 may decode an address that is externally input and may select one of the word lines WL of the memory cell array 1. The address decoded in the row decoder 2 may be provided to a row driver (not shown), and in response to a control operation of control circuits, the row driver may provide a certain voltage to a selected word line WL and each of non-selected word lines WL.

In response to an address decoded from the column decoder 4, the sense amplifier 3 may detect and amplify a voltage difference between a selected bit line BL and a reference bit line, and may then output the amplified voltage difference.

The column decoder 4 may provide a data delivery pathway between the sense amplifier 3 and an external device (e.g., a memory controller). The column decoder 4 may decode an address externally input and may select one of the bit lines BL.

The control logic 5 may generate control signals that control operations to write data to the memory cell array 1 and/or to read data from the memory cell array 1.

FIGS. 1B, 1C, and 1D illustrate simplified perspective views showing a semiconductor device according to some embodiments.

Referring to FIG. 1B, a semiconductor device may include a substrate 100, a peripheral circuit structure PS on the substrate 100, and a cell array structure CS on the peripheral circuit structure PS.

The peripheral circuit structure PS may include core/peripheral circuits formed on the substrate 100. The core/peripheral circuits may include the row and column decoders (see 2 and 4 of FIG. 1A), the sense amplifier (see 3 of FIG. 1A), and the control logics (see 5 of FIG. 1A).

The substrate 100 may have a planar or plate shape elongated along a plane defined in a first direction D1 and a second direction D2. The first direction D1 and the second direction D2 may intersect each other. For example, the first direction D1 and the second direction D2 may be horizontal directions that are orthogonal to each other. The peripheral circuit structure PS and the cell array structure CS may be sequentially stacked in a third direction D3 on the substrate 100. The third direction D3 may intersect the first direction D1 and the second direction D2. For example, the third direction D3 may be a vertical direction perpendicular to the first direction D1 and the second direction D2.

The cell array structure CS may include bit lines BL, source lines SL, and memory cells MC between the bit lines BL and the source lines SL. Each of the memory cells MC may be connected to one word line WL, one bit line BL, and one source line SL.

Referring to FIG. 1C, a semiconductor device may include a cell array structure CS on a substrate 100 and a peripheral circuit structure PS on the cell array structure CS. The cell array structure CS may be disposed between the substrate 100 and the peripheral circuit structure PS. The peripheral circuit structure PS may include core/peripheral circuits.

Referring to FIG. 1D, a semiconductor device may have a chip-to-chip (C2C) structure. A peripheral circuit structure PS may include a first substrate 100a. Lower metal pads LMP may be provided on an uppermost portion of the peripheral circuit structure PS. The lower metal pads LMP may be electrically connected to core/peripheral circuits. The lower metal pads LMP may be bonded to upper metal pads UMP of a cell array structure CS. Spatially relative terms such as ‘on,’ ‘above,’ ‘upper,’ ‘beneath,’ ‘below,’ ‘lower,’ ‘side,’ and the like may be used herein to describe elements or features with reference to the drawings. However, it will be understood that such spatially relative terms are intended to encompass different orientations of the device in use or operation in addition to the orientation depicted in the figures. For example, if the device in the figures is turned over, elements described as below or beneath other elements or features would then be oriented above the other elements or features.

The cell array structure CS may include a second substrate 200a, and the upper metal pads UMP may be provided on a lowermost portion of the cell array structure CS. The upper metal pads UMP may be electrically connected to the bit lines BL, the source lines SL, and the word lines WL. The upper metal pads UMP may be electrically connected to the memory cells MC.

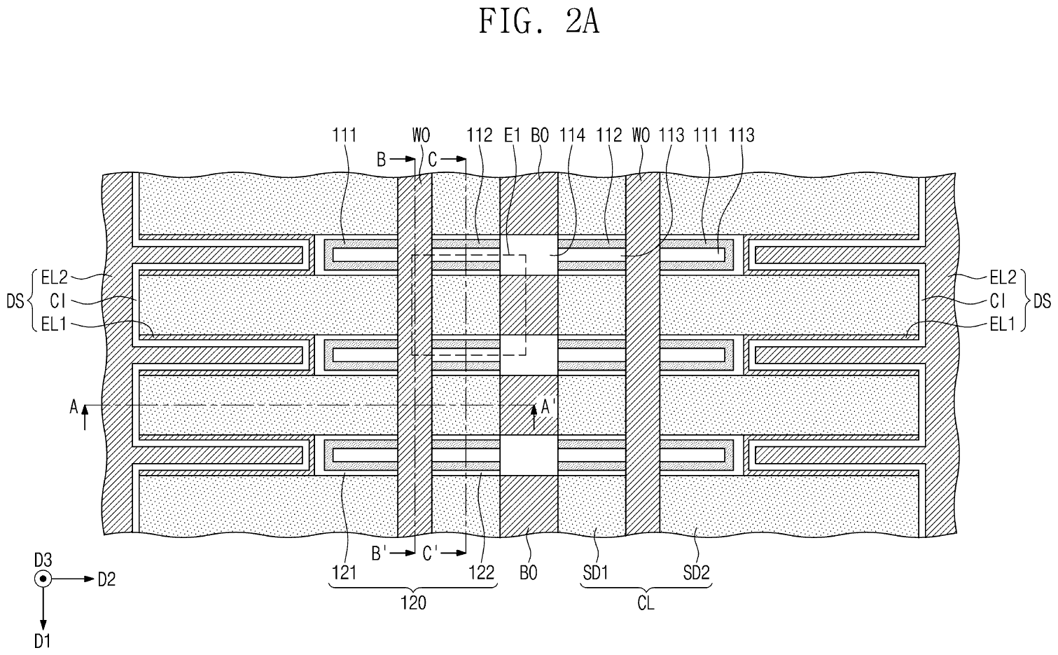

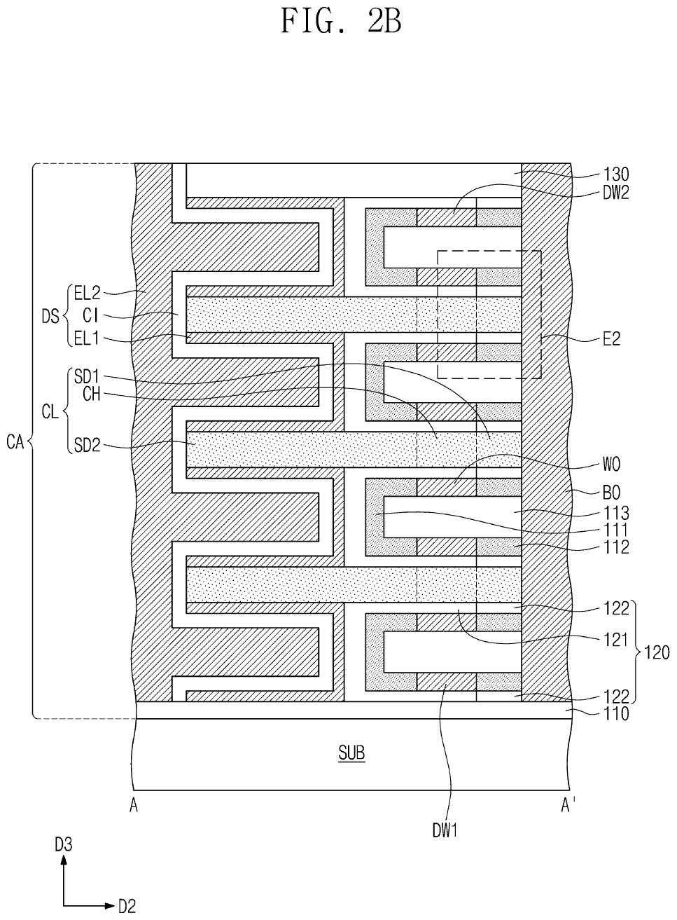

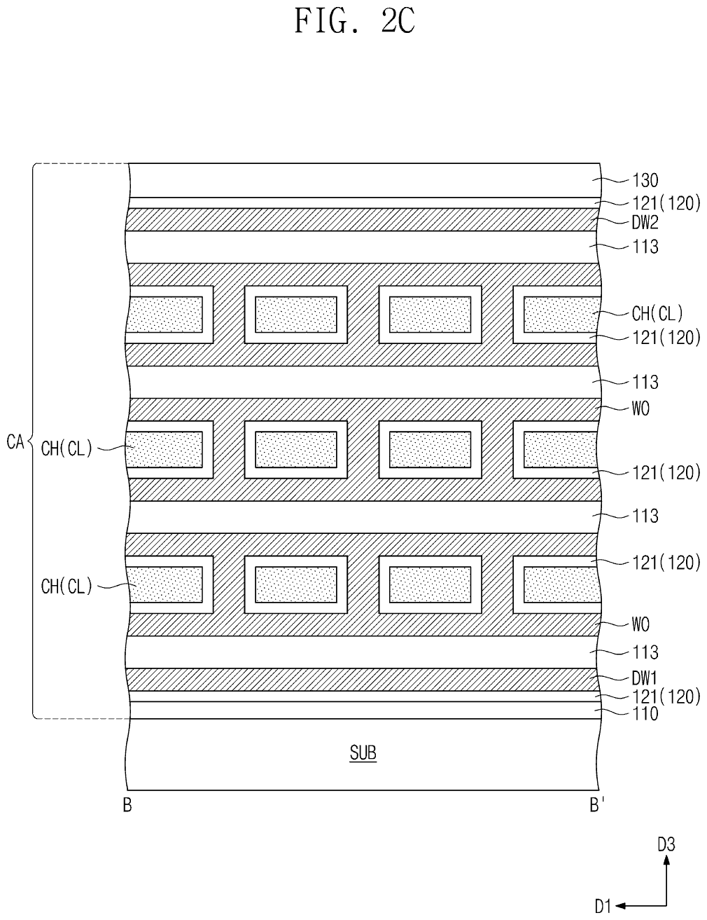

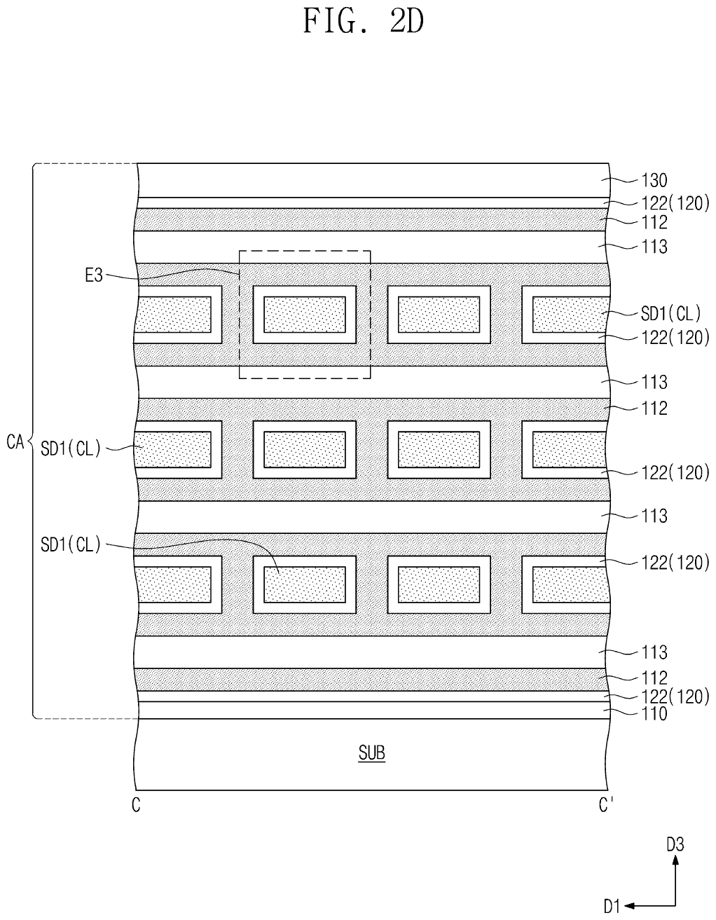

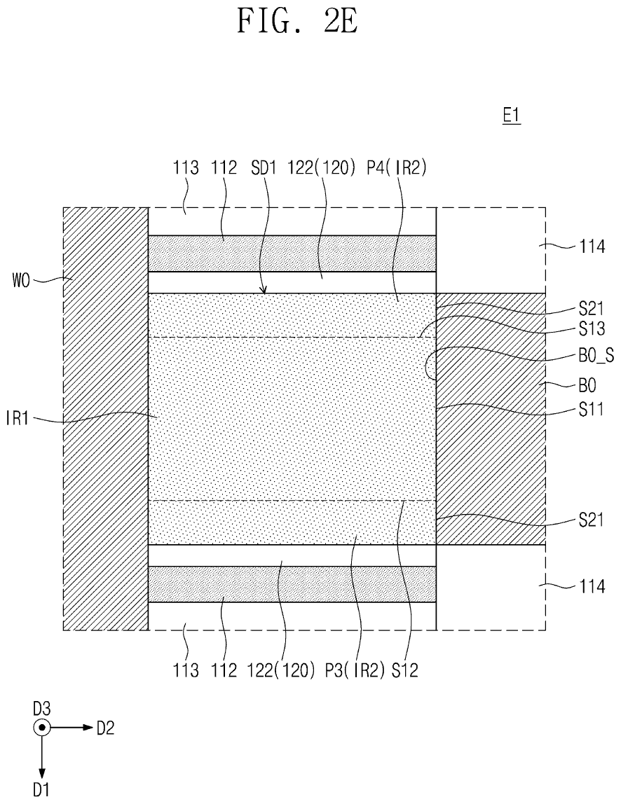

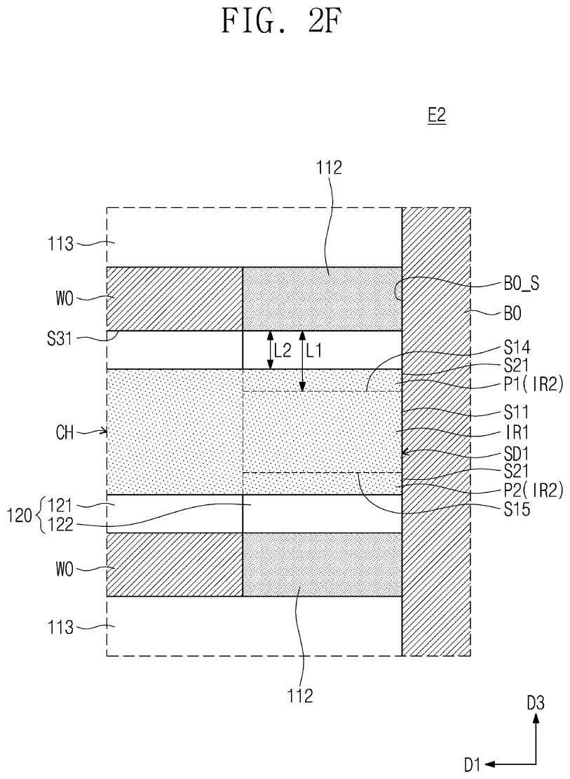

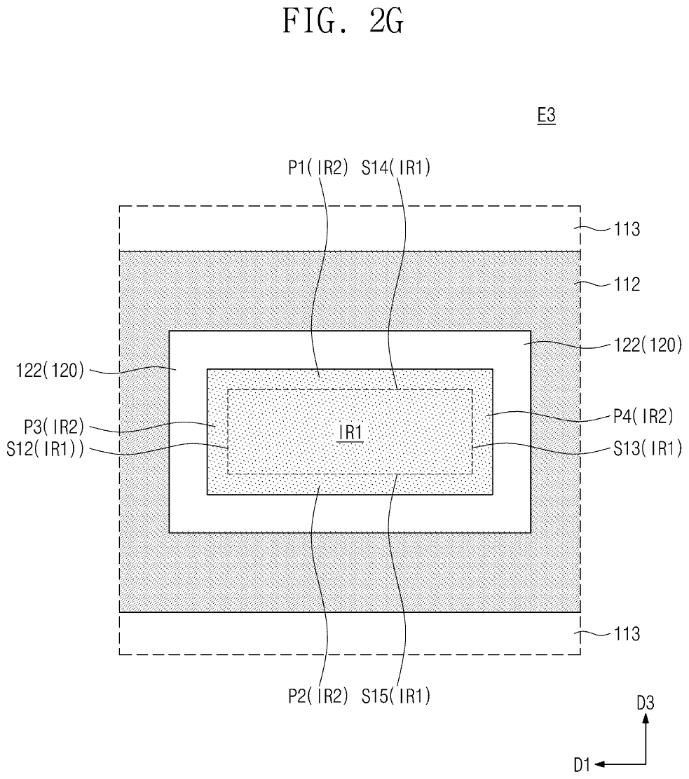

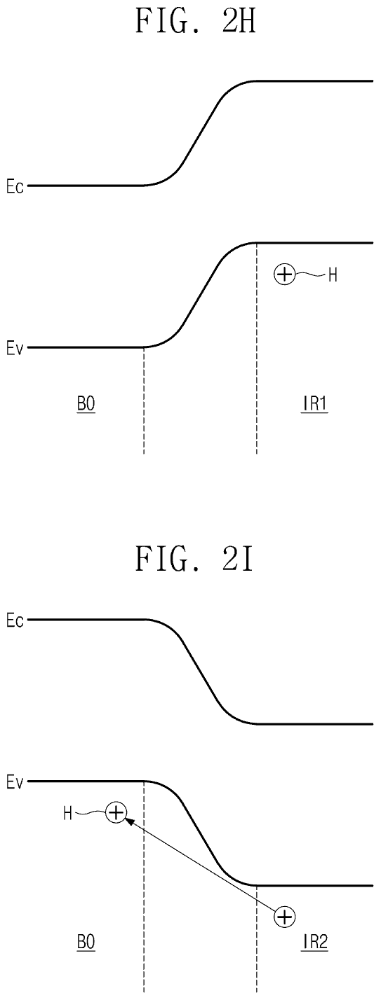

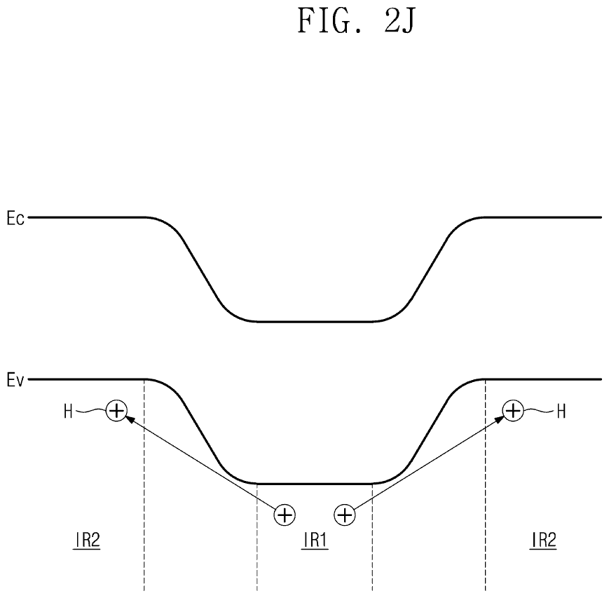

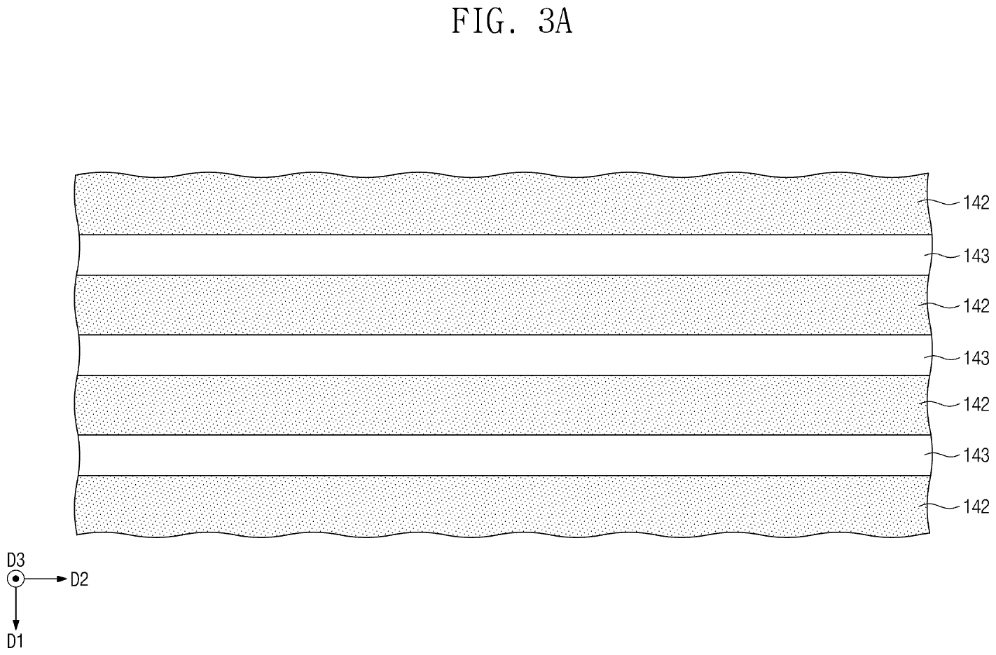

FIG. 2A illustrates a plan view showing a semiconductor device according to some embodiments. FIG. 2B illustrates a cross-sectional view taken along line A-A′ of FIG. 2A. FIG. 2C illustrates a cross-sectional view taken along line B-B′ of FIG. 2A. FIG. 2D illustrates a cross-sectional view taken along line C-C′ of FIG. 2A. FIG. 2E illustrates an enlarged view showing section E1 of FIG. 2A. FIG. 2F illustrates an enlarged view showing section E2 of FIG. 2B. FIG. 2G illustrates an enlarged view showing section E3 of FIG. 2D.

Referring to FIGS. 2A, 2B, 2C, and 2D, a semiconductor device may include a substrate SUB. The substrate SUB may have a planar or plate shape elongated along a plane defined in a first direction D1 and a second direction D2.

The substrate SUB may be a semiconductor substrate. For example, the substrate SUB may include silicon, germanium, or silicon-germanium. In some embodiments, the substrate SUB may be a dielectric substrate, a silicon-on-insulator (SOI) substrate, or a germanium-on-insulator (GOI) substrate.

A cell array structure CA may be provided on the substrate SUB. The cell array structure CA may include a lower dielectric layer 110, a channel pattern CL, a bit line BO, word line WO, a first dummy word line DW1, a second dummy word line DW2, a first dielectric pattern 111, a second dielectric pattern 112, a filling pattern 113, an intervening pattern 114, a data storage structure DS, a gate dielectric structure 120, and an upper dielectric layer 130.

The lower dielectric layer 110 may be provided on the substrate SUB. The lower dielectric layer 110 may include a dielectric material. In some embodiments, the lower dielectric layer 110 may include a plurality of dielectric layers. In some embodiments, peripheral transistors may be disposed between the substrate SUB and the lower dielectric layer 110.

The bit lines BO may be provided on the lower dielectric layer 110. The bit line BO may extend in a third direction D3. The third direction D3 may intersect the first direction D1 and the second direction D2. For example, the third direction D3 may be a vertical direction perpendicular to the first direction D1 and the second direction D2.

One bit line BO may be electrically connected to the channel patterns CL that overlap in the third direction D3. The channel patterns CL may be connected to opposite sides of one bit line BO. In some embodiments, the channel patterns CL may be connected to only side of one bit line BO.

The bit lines BO may be arranged spaced apart from each other in the first direction D1. The bit line BO may be spaced apart in the second direction D2 from the data storage structure DS. The bit line BO may include a conductive material. For example, the bit line BO may include polysilicon.

The intervening pattern 114 may be provided between the bit lines BO. The intervening patterns 114 may be arranged spaced apart from each other in the first direction D1. The intervening patterns 114 and the bit lines BO may be alternately arranged along the first direction D1. The intervening pattern 114 may extend in the third direction D3. The intervening pattern 114 may be provided on the lower dielectric layer 110. The intervening pattern 114 may include a dielectric material. In some embodiments, the intervening pattern 114 may be a multiple layer including a plurality of dielectric layers.

The data storage structure DS may be provided on the lower dielectric layer 110. The data storage structure DS may be a capacitor including first electrodes EL1, a second electrode EL2, and a capacitor dielectric layer CI. The first electrodes EL1 may be spaced apart from the second electrode EL2. The capacitor dielectric layer CI may be provided between the first electrode EL1 and the second electrode EL2. The first and second electrodes EL1 and EL2 may include a conductive material. The capacitor dielectric layer CI may include a dielectric material.

In some embodiments, the data storage structure DS may be a variable resistance pattern whose two resistance states are switched with an electrical pulse. In this case, the data storage structure DS may include a phase-change material whose crystalline state is changed based on an amount of current, perovskite compounds, transition metal oxide, magnetic materials, ferromagnetic materials, or antiferromagnetic materials.

The channel patterns CL may overlap each other in the third direction D3. The channel patterns CL may be arranged in the first direction D1. The channel pattern CL may extend in the second direction D2. The channel pattern CL may be disposed between the data storage structure DS and the bit line BO. The channel pattern CL may be electrically connected to the data storage structure DS and the bit line BO. The channel pattern CL may be in contact with the data storage structure DS and the bit line BO. The data storage structure DS and the bit line BO may be electrically connected to each other by a plurality of channel patterns CL that overlap in the third direction D3.

The channel pattern CL may include at least one selected from a monocrystalline a semiconductor, a polycrystalline semiconductor, an oxide semiconductor, or a two-dimensional material. The monocrystalline semiconductor may be, for example, monocrystalline silicon. The polycrystalline semiconductor may be, for example, polysilicon. The oxide semiconductor may be, for example, indium gallium zinc oxide (IGZO). The two-dimensional material may be, for example, MoS₂, WS₂, MoSe₂, or WSe₂.

The channel pattern CL may include a first source/drain region SD1, a second source/drain region SD2, and a channel region CH. The second source/drain region SD2 of the channel pattern CL may be in contact with the first electrode EL1 and the capacitor dielectric layer CI of the data storage structure DS. The first electrode EL1 may be provided between the channel patterns CL. The first source/drain region SD1 of the channel pattern CL may be in contact with the bit line BO. The channel region CH of the channel pattern CL may be provided between the first and second source/drain regions SD1 and SD2. The first source/drain region SD1 may be provided between the word line WO and the bit line BO. The second source/drain region SD2 may be provided between the word line WO and the data storage structure DS, or more particularly, between the channel region and the data storage structure. The channel region CH may overlap in the third direction D3 with the word line WO. Components or layers described with reference to “overlap” in a particular direction may be at least partially obstructed by one another when viewed along a line extending in the particular direction or in a plane perpendicular to the particular direction. The first and second source/drain regions SD1 and SD2 may be doped with impurities.

The word line WO may extend in the first direction D1. The word lines WO may overlap each other in the third direction D3. The word line WO may be provided between the bit line BO and the data storage structure DS. The word line WO may be spaced apart in the second direction D2 from the bit line BO. The word line WO may be spaced apart in the second direction D2 from the data storage structure DS. The word lines WO spaced apart from each other in the second direction D2 may be provided on opposite sides of the bit line BO. The bit line BO may be disposed between the word lines WO spaced apart from each other in the second direction D2. The channel pattern CL may extend in the second direction D2 to penetrate the word line WO. When viewed in vertical section as shown in FIG. 2C, the word line WO may surround the channel patterns CL arranged in the first direction D1. The word line WO may include a conductive material.

The first and second dummy word lines DW1 and DW2 may overlap in the third direction D3 with the word lines WO. The first and second dummy word lines DW1 and DW2 may extend in the first direction D1. The first dummy word line DW1 may be located at a level lower than that of the word lines WO, relative to the substrate SUB. The second dummy word line DW2 may be located at a level higher than that of the word lines WO, relative to the substrate SUB. The first and second dummy word lines DW1 and DW2 may include a conductive material.

The gate dielectric structure 120 may include a gate dielectric layer 121 and a capping dielectric layer 122. The gate dielectric layer 121 may be in contact with the word line WO, the channel pattern CL, and the first electrode EL1 of the data storage structure DS. The gate dielectric layer 121 may be provided between the word line WO and the channel pattern CL. In some embodiments, the gate dielectric layer 121 may be in contact with the second source/drain region SD2 and the channel region CH of the channel pattern CL. The gate dielectric layer 121 may be spaced apart from the bit line BO.

The capping dielectric layer 122 may be in contact with the bit line BO and the channel pattern CL. The capping dielectric layer 122 may be provided between the gate dielectric layer 121 and the bit line BO. In some embodiments, the capping dielectric layer 122 may be in contact with the first source/drain region SD1 of the channel pattern CL. The capping dielectric layer 122 may be spaced apart from the first electrode EL1 of the data storage structure DS. The gate dielectric layer 121 may be provided between the capping dielectric layer 122 and the first electrode EL1 of the data storage structure DS.

The gate dielectric layer 121 and the capping dielectric layer 122 may include a dielectric material. For example, the gate dielectric layer 121 may include oxide, and the capping dielectric layer 122 may include oxide or nitride.

The first dielectric pattern 111 may be in contact with the word line WO and the gate dielectric layer 121. The first dielectric pattern 111 may be spaced apart from the bit line BO and the first electrode EL1 of the data storage structure DS. The gate dielectric layer 121 may be provided between the first dielectric pattern 111 and the first electrode EL1 of the data storage structure DS. The first dielectric pattern 111 may include a dielectric material. For example, the first dielectric pattern 111 may include nitride.

The second dielectric pattern 112 may be in contact with the bit line BO, the word line WO, and the capping dielectric layer 122. The second dielectric pattern 112 may be spaced apart from the first electrode EL1 of the data storage structure DS. The word line WO and the first dielectric pattern 111 may be provided between the second dielectric pattern 112 and the first electrode EL1 of the data storage structure DS. The second dielectric pattern 112 may include a dielectric material. For example, the second dielectric pattern 112 may include nitride.

The filling pattern 113 may be in contact with the word line WO, the bit line BO, the first dielectric pattern 111, and the second dielectric pattern 112. The filling pattern 113 may be spaced apart from the first electrode EL1 of the data storage structure DS. The gate dielectric layer 121 and the first dielectric pattern 111 may be provided between the filling pattern 113 and the first electrode EL1 of the data storage structure DS. The filling pattern 113 may include a dielectric material. For example, the filling pattern 113 may include oxide.

The upper dielectric layer 130 may be disposed at an uppermost portion of the cell array structure CA. The upper dielectric layer 130 may include a dielectric material. In some embodiments, the upper dielectric layer 130 may be a multiple layer including a plurality of dielectric layers.

Referring to FIGS. 2E, 2F, and 2G, the first source/drain region SD1 may include a first impurity region IR1 and a second impurity region IR2. The first impurity region IR1 may have a first conductivity type. The second impurity region IR2 may have a second conductivity type different from the first conductivity type. For example, the first conductivity type may be of n-type, and electrons may be majority carriers of the first impurity region IR1. The second conductivity type may be of p-type, and holes may be majority carriers of the second impurity region IR2.

The first impurity region IR1 may include first impurities of the first conductivity type. The second impurity region IR2 may include second impurities of the second conductivity type. For example, the first impurities may be n-type impurities (e.g., P, As, Sb, and Bi), and the second impurities may be p-type impurities (e.g., B, Al, Ga, and In). In some embodiments, the second impurity region IR2 may include the first impurities and the second impurities, and a concentration of the second impurities may be greater than that of the first impurities. In this case, the second impurity region IR2 may include p-type impurities and n-type impurities, and a concentration of the p-type impurities may be greater than that of the n-type impurities. In some embodiments, when the second impurity region IR2 includes the first impurities and the second impurities, a concentration of the second impurities in the second impurity region IR2 may decrease with decreasing distance from (i.e., in a direction toward) the first impurity region IR1.

The first impurity region IR1 and the second impurity region IR2 may be disposed between the word line WO and the bit line BO, or more particularly, between the channel region and the bit line BO. The first impurity region IR1 and the second impurity region IR2 may be in contact with the bit line BO. The first impurity region IR1 and the second impurity region IR2 may be in contact with the channel region CH. The first impurity region IR1 and the second impurity region IR2 may be disposed between and connect the channel region CH and the bit line BO.

For ease of description and illustration, the term “surface” may be used herein to define structural surfaces of elements or features, and also to define boundaries of impurity regions in the elements or features. A first boundary or surface S11 of the first impurity region IR1 and a boundary or surface S21 of the second impurity region IR2 may be in contact with a sidewall BO_S of the bit line BO. The first surface S11 of the first impurity region IR1 and the surface S21 of the second impurity region IR2 may be coplanar with each other. The first surface S11 of the first impurity region IR1 and the surface S21 of the second impurity region IR2 may be parallel to the first direction D1 and the third direction D3. When viewed in vertical or other cross-section, the surface S21 of the second impurity region IR2 may surround the first surface S11 of the first impurity region IR1.

The first impurity region IR1 may be spaced apart from the capping dielectric layer 122 of the gate dielectric structure 120. The second impurity region IR2 may be in contact with the capping dielectric layer 122 of the gate dielectric structure 120. The second impurity region IR2 may be provided between the first impurity region IR1 and the capping dielectric layer 122 of the gate dielectric structure 120. When viewed in cross-section as shown in FIG. 2G, the second impurity region IR2 may surround the first impurity region IR1.

The first impurity region IR1 may have a top surface S14, a bottom surface S15, and a second surface S12 and a third surface S13 that connect the top surface S14 and the bottom surface S15 to each other. The second surface S12 and the third surface S13 of the first impurity region IR1 may be opposite to each other. The first, second, and third surfaces S11, S12, and S13 of the first impurity region IR1 may be sidewalls of the first impurity region IR1. The top surface S14 and the bottom surface S15 of the first impurity region IR1 may be parallel to the first direction D1 and the second direction D2. The second surface S12 and the third surface S13 of the first impurity region IR1 may be parallel to the second direction D2 and the third direction D3.

The second impurity region IR2 may include a first portion P1 in contact with the top surface S14 of the first impurity region IR1, a second portion P2 in contact with the bottom surface S15 of the first impurity region IR1, a third portion P3 in contact with the second surface S12 of the first impurity region IR1, and a fourth portion P4 in contact with the third surface S13 of the first impurity region IR1. The first impurity region IR1 may be surrounded by the first, second, third, and fourth portions P1, P2, P3, and P4 of the second impurity region IR2. The term “surround” or “cover” or “fill” as may be used herein may not require completely surrounding or covering or filling the described elements or layers, but may, for example, refer to partially surrounding or covering or filling the described elements or layers. The first impurity region IR1 may be disposed between the first and second portions P1 and P2 of the second impurity region IR2. The first impurity region IR1 may be disposed between the third and fourth portions P3 and P4 of the second impurity region IR2.

A distance between the first impurity region IR1 and the word line WO (or more particularly, between the first impurity region IR1 and the second dielectric pattern 112 between the word line WO and the bit line BO) may be greater than a distance between the second impurity region IR2 and the word line WO (or between the second impurity region IR2 and the second dielectric pattern 112). The word line WO may have a surface S31 that is adjacent in the third direction D3 to the top surface S14 of the first impurity region IR1 and is adjacent in the third direction D3 to the first portion P1 of the second impurity region IR2. The top surface S14 of the first impurity region IR1 may be spaced apart in the third direction D3 at a first distance L1 from the surface S31 of the word line WO (or from the second dielectric pattern 112). The first portion P1 of the second impurity region IR2 may be spaced apart in the third direction D3 at a second distance L2 from the surface S31 of the word line WO (or from the second dielectric pattern 112). The first distance L1 may be greater than the second distance L2.

The first impurity region IR1 and the second impurity region IR2 may extend in the second direction D2. A length in the second direction D2 of the first impurity region IR1 may be the same as a length in the second direction D2 of the second impurity region IR2. That is, the first impurity region IR1 and the second impurity region IR2 may each extend over an entirety of the length between the word line WO and the bit line BO in the second direction D2.

In the semiconductor device according to some embodiments, as the first source/drain region SD1 includes the first impurity region IR1 and the second impurity region IR2 of opposite conductivity types, a floating body effect may be reduced or prevented, and the semiconductor device may improve in electrical properties.

FIGS. 2H, 2I, and 2J illustrate energy band diagrams of a semiconductor device according to some embodiments. FIG. 2H shows an energy band diagram between a bit line and a first impurity region. FIG. 2I shows an energy band diagram between a bit line and a second impurity region. FIG. 2J shows an energy band diagram between a first impurity region and a second impurity region. The energy band diagrams of FIGS. 2H, 2I, and 2J may illustrate an example where a first impurity region includes n-type silicon, a second impurity region includes p-type silicon, and a bit line includes polysilicon.

Referring to FIG. 2H, in accordance with the energy band diagram of the first impurity region IR1 and the bit line BO, holes H may be prevented or restricted from moving from the first impurity region IR1 toward the bit line BO.

Referring to FIGS. 2I and 2J, in accordance with the energy band diagram of the second impurity region IR2 and the bit line BO and the energy band diagram of the first and second impurity regions IR1 and IR2, holes H may move from the first impurity region IR1 toward the second impurity region IR2, and may move from the second impurity region IR2 toward the bit line BO. Therefore, holes H in the first and second impurity regions IR1 and IR2 may move toward the bit line BO from the first and second impurity regions IR1 and IR2, and a floating body effect caused by holes H may be reduced or prevented.

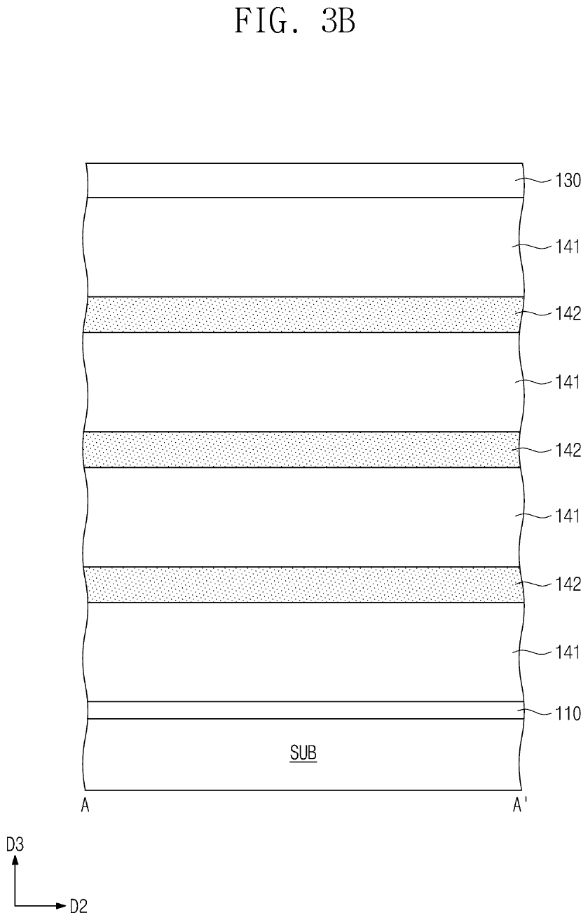

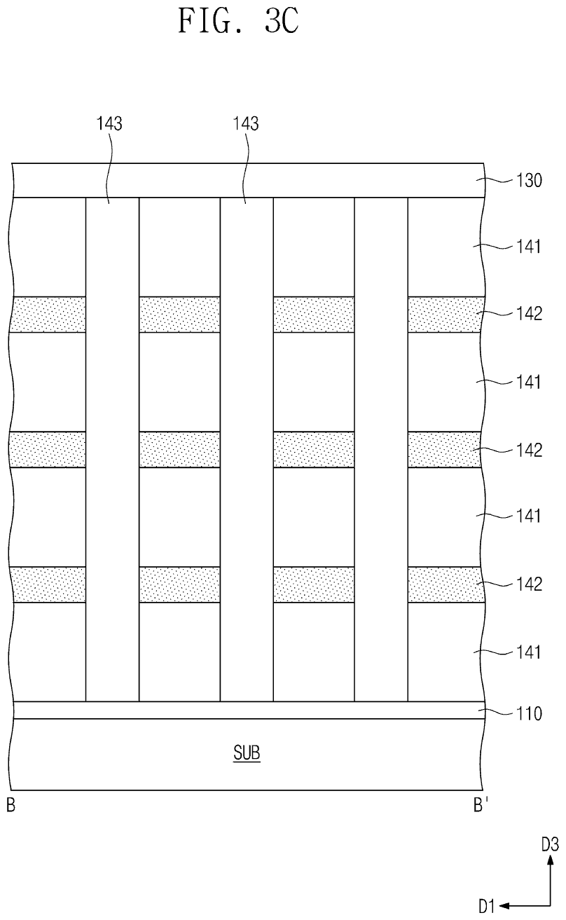

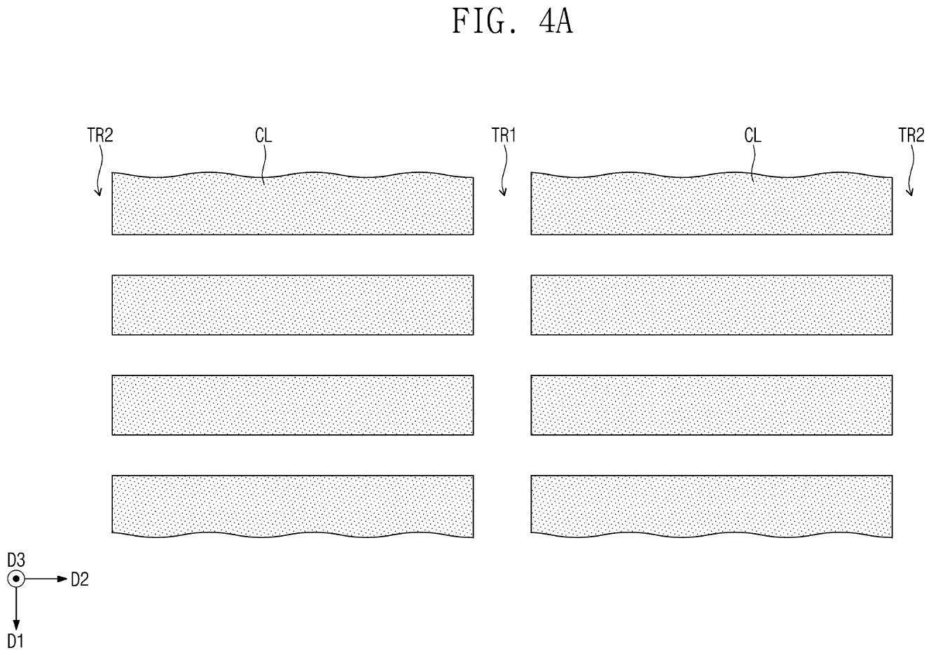

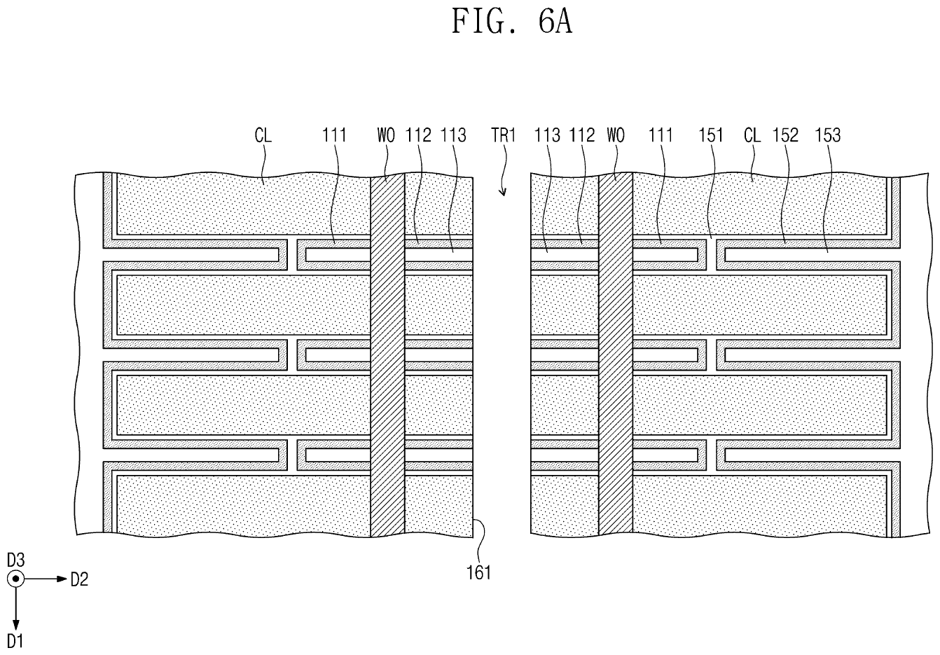

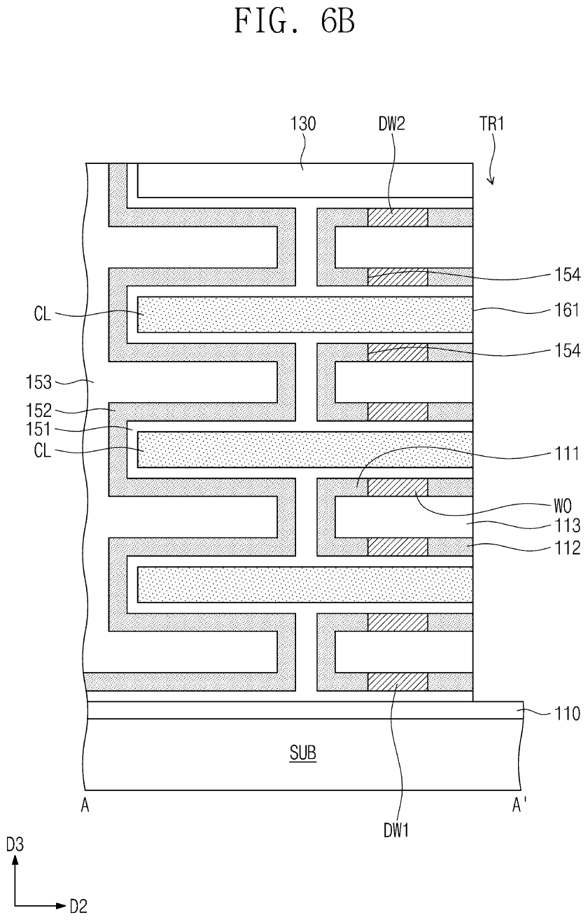

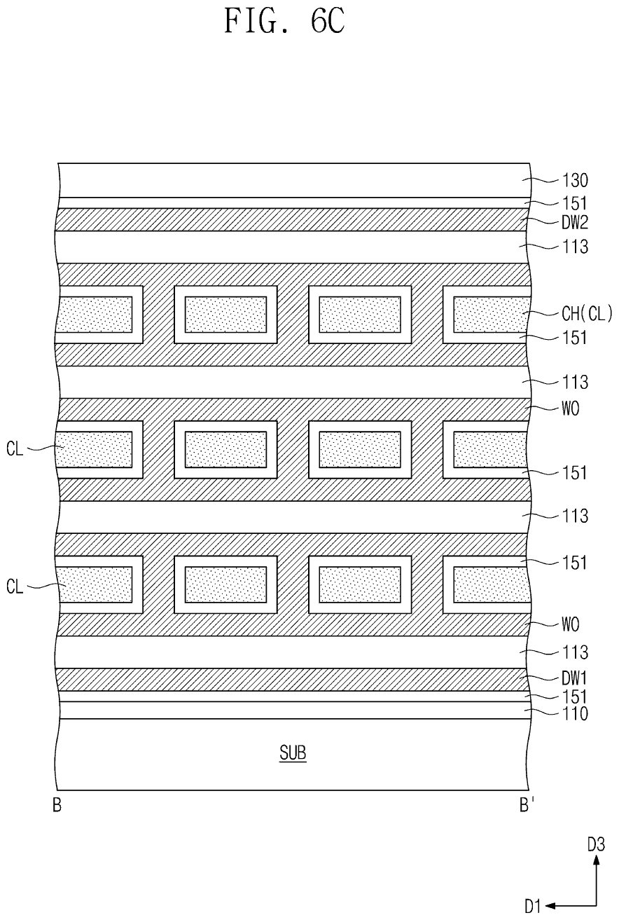

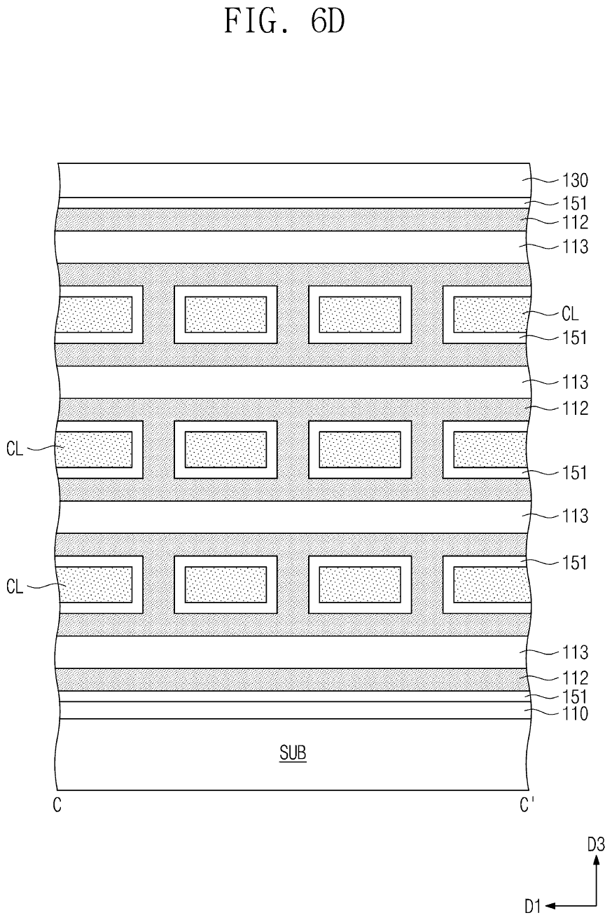

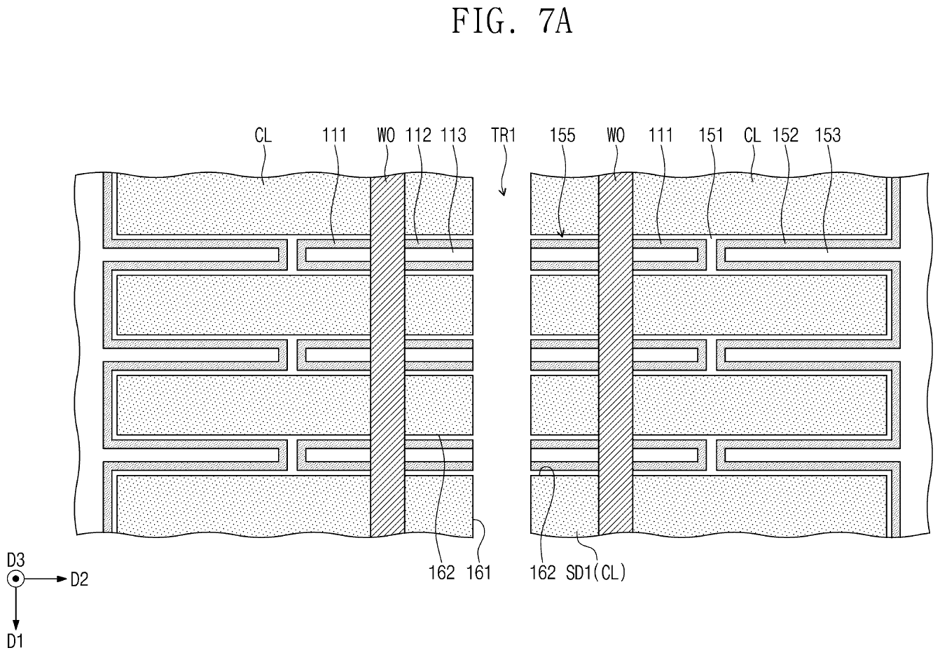

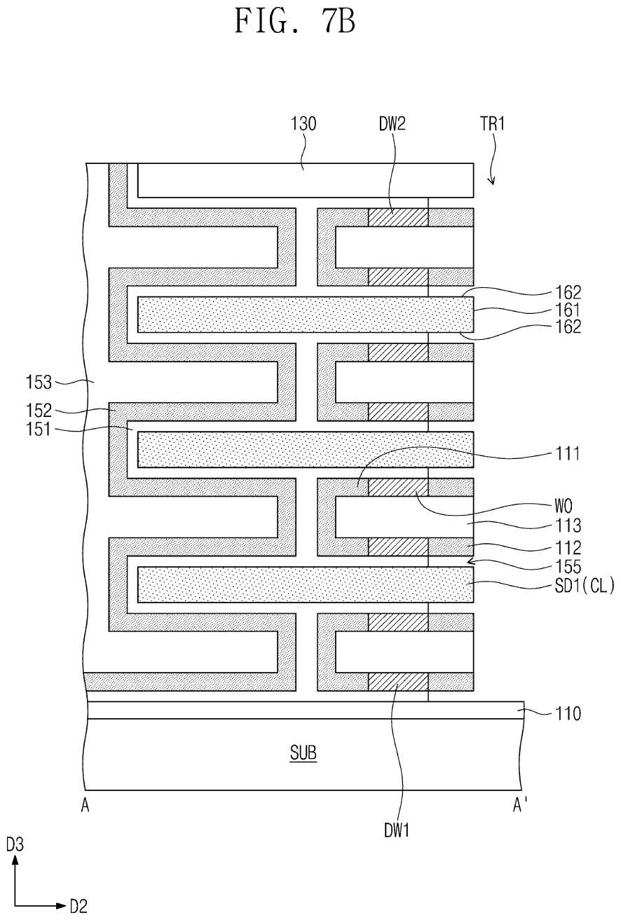

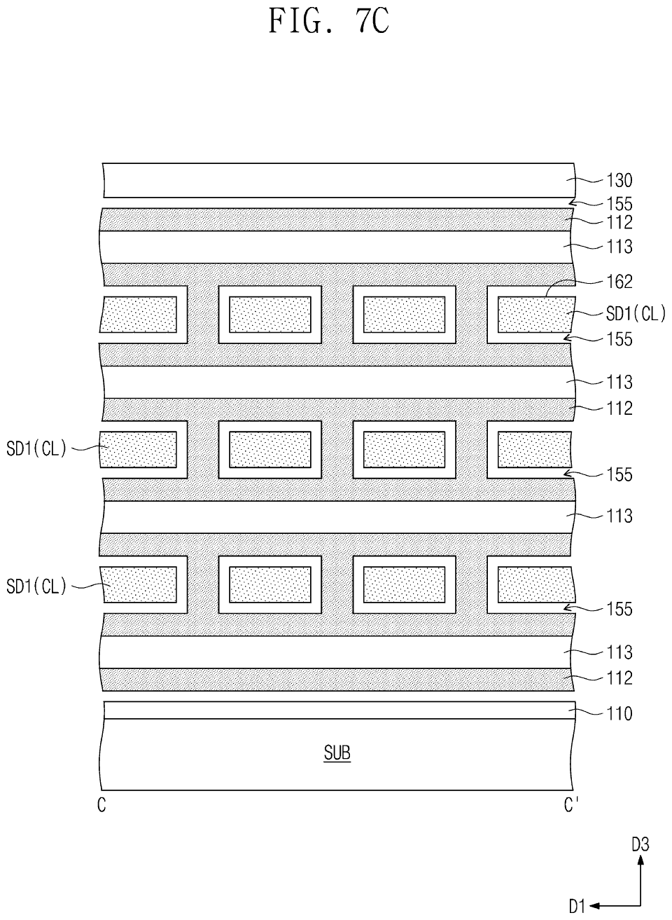

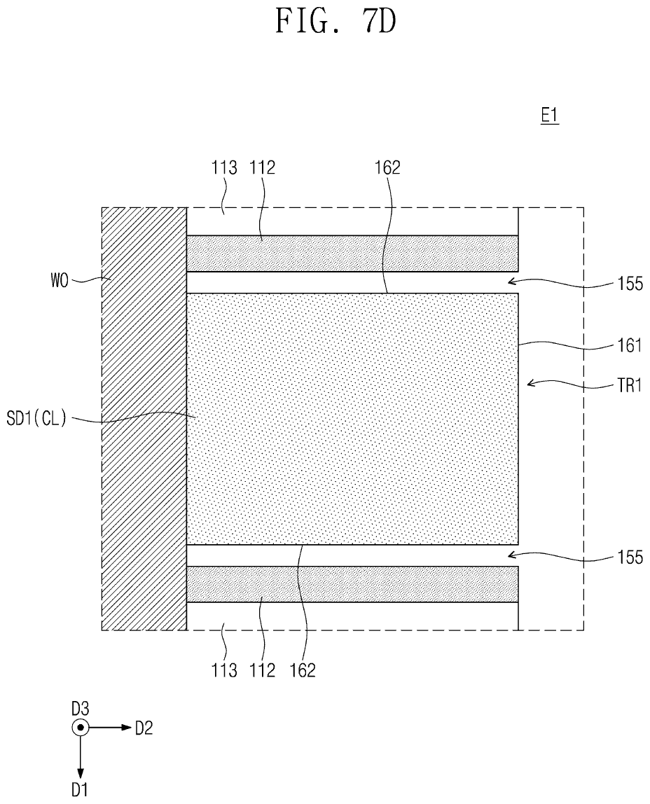

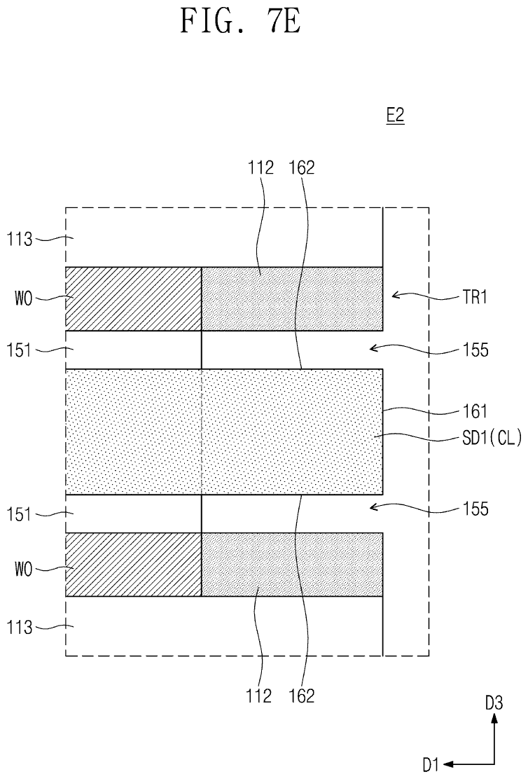

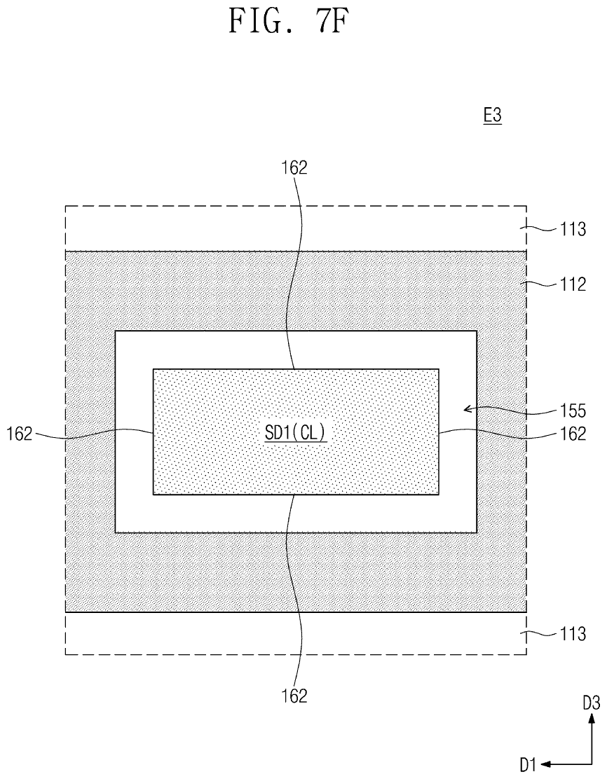

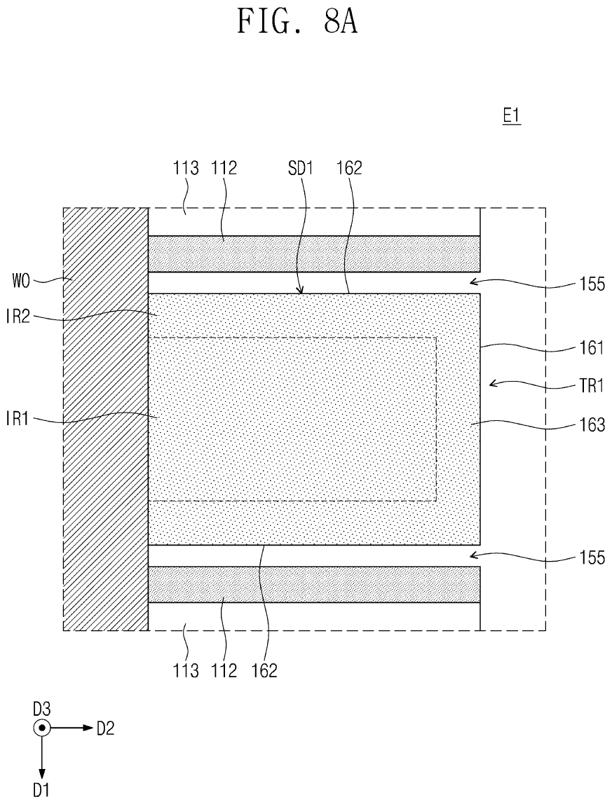

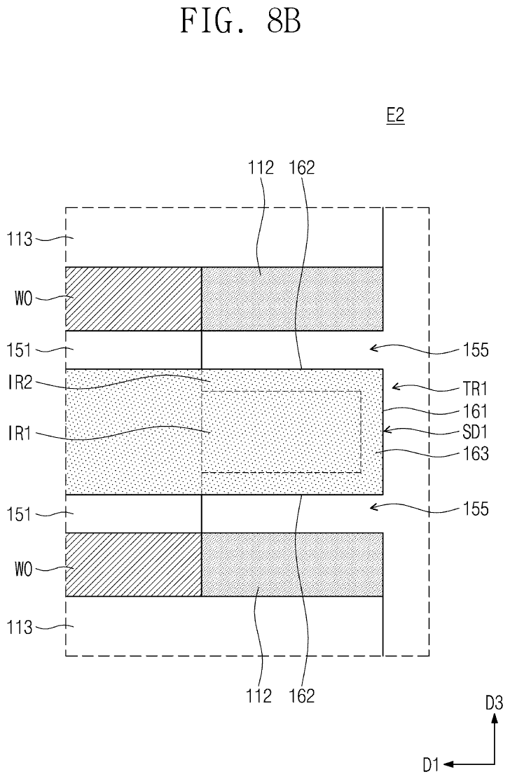

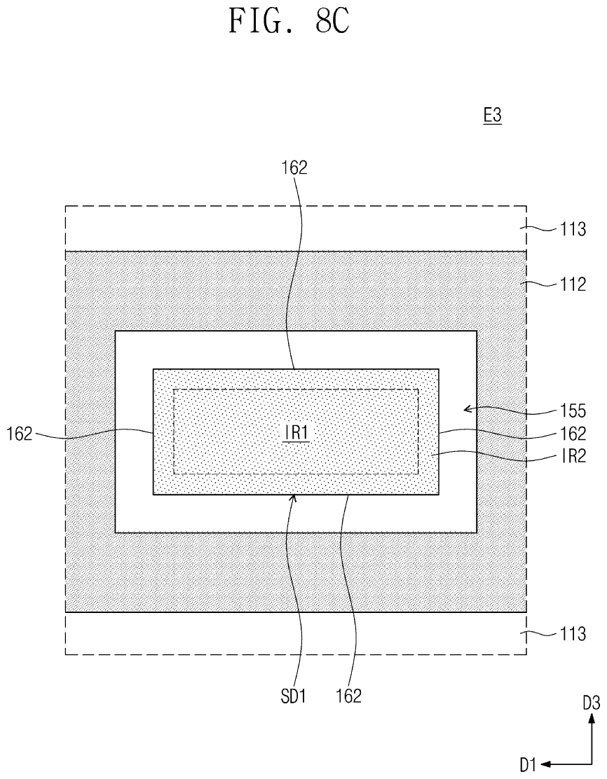

FIGS. 3A, 3B, 3C, 4A, 4B, 4C, 5A, 5B, 5C, 6A, 6B, 6C, 7A, 7B, 7C, 7D, 7E, 7F, 8A, 8B, 8C, 9A, 9B, 9C, 9D, 9E, 10A, and 10B illustrate diagrams showing a method of fabricating a semiconductor device according to some embodiments. FIGS. 3A, 4A, 5A, 6A, 7A, 9A, and 10A may correspond to FIG. 2A. FIGS. 3B, 4B, 5B, 6B, 7B, 9B, and 10B may correspond to FIG. 2B. FIGS. 3C, 4C, 5C, and 6C may correspond to FIG. 2C. FIGS. 6D, 7C, and 9C may correspond to FIG. 2D. FIGS. 7D, 8A, and 9D may correspond to FIG. 2E. FIGS. 7E, 8B, and 9E may correspond to FIG. 2F. FIGS. 7F and 8C may correspond to FIG. 2G.

Referring to FIGS. 3A, 3B, and 3C, a substrate SUB may be formed. A lower dielectric layer 110 may be formed on the substrate SUB. Sacrificial layers 141 and preliminary channel layers 142 may be formed on the lower dielectric layer 110. The sacrificial layers 141 and the preliminary channel layers 142 may be alternately stacked on each other along a third direction D3. The preliminary channel layer 142 and the sacrificial layer 141 may have etch selectivity with respect to each other. For example, the preliminary channel layer 142 may include silicon, and the sacrificial layer 141 may include silicon-germanium.

Separation patterns 143 may be formed which extend in the third direction D3 to penetrate the preliminary channel layers 142 and the sacrificial layers 141. The separation pattern 143 may extend in a second direction D2. The separation patterns 143 may divide the preliminary channel layer 142 into a plurality of preliminary channel layers 142 that are arranged in a first direction D1. The separation patterns 143 may divide the sacrificial layer 141 into a plurality of sacrificial layers 141 that are arranged in the first direction D1. The separation pattern 143 may include a dielectric material. In some embodiments, the separation pattern 143 may be a multiple layer including a plurality of dielectric layers.

An upper dielectric layer 130 may be formed on the separation patterns 143 and the sacrificial layers 141.

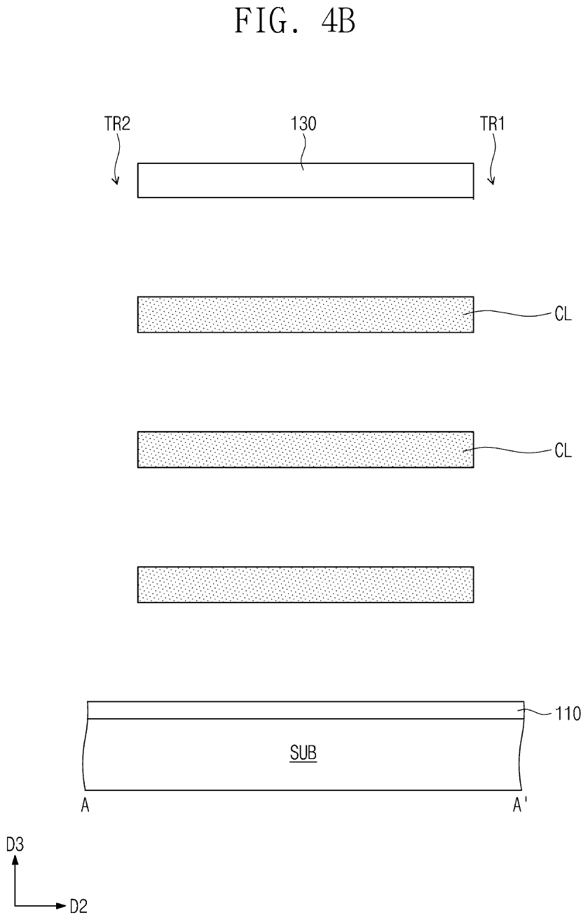

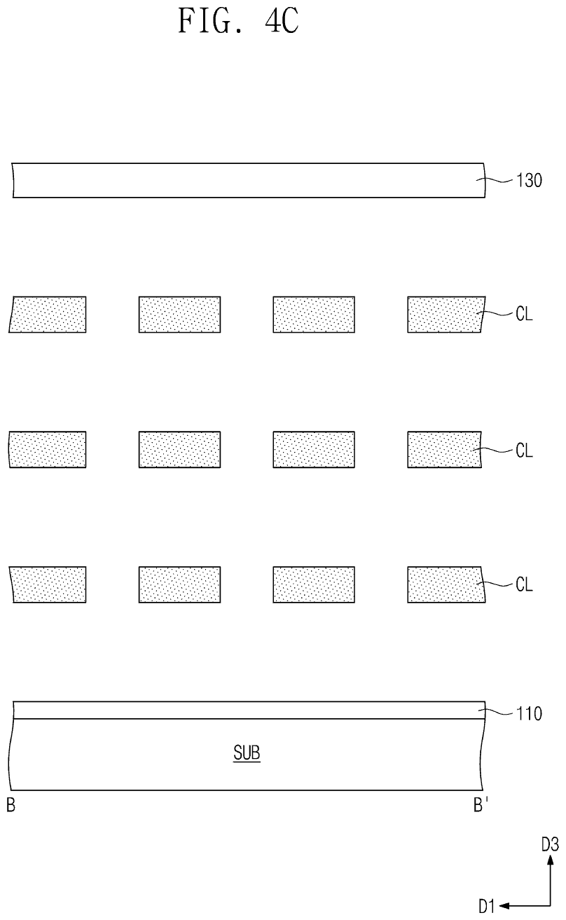

Referring to FIGS. 4A, 4B, and 4C, a first trench TR1 and second trenches TR2 may be formed which extend in the third direction D3 to penetrate the upper dielectric layer 130, the sacrificial layers 141, the preliminary channel layers 142, and the separation patterns 143. The first and second trenches TR1 and TR2 may extend in the first direction D1. The first and second trenches TR1 and TR2 may be arranged spaced apart from each other in the second direction D2. The first trench TR1 may be disposed between the second trenches TR2.

The first and second trenches TR1 and TR2 may divide the preliminary channel layer 142 into channel patterns CL.

The sacrificial layers 141 and the separation patterns 143 may be removed through the first and second trenches TR1 and TR2. In some embodiments, the removal of the sacrificial layers 141 and the separation patterns 143 may include selectively removing the sacrificial layers 141 and selectively removing the separation patterns 143.

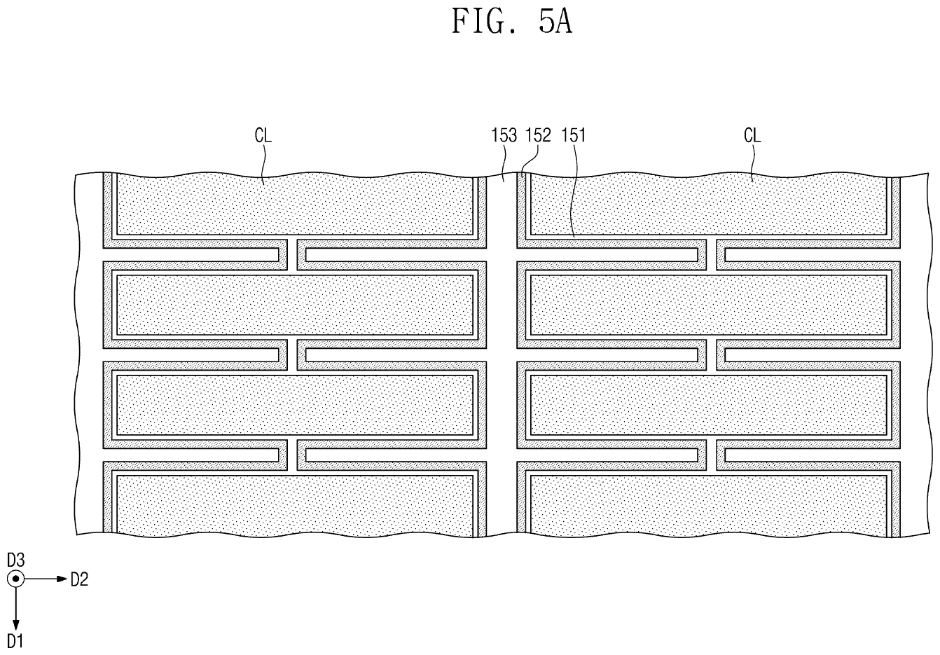

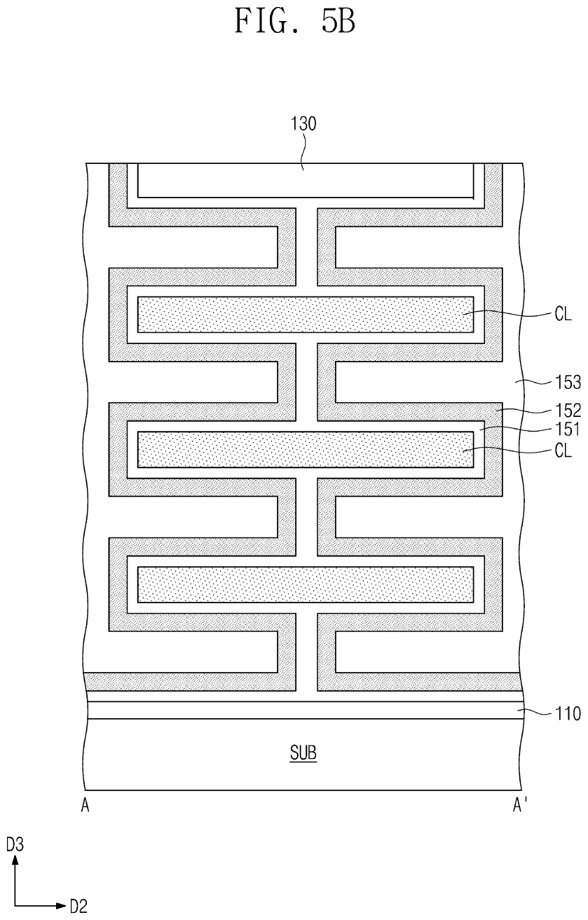

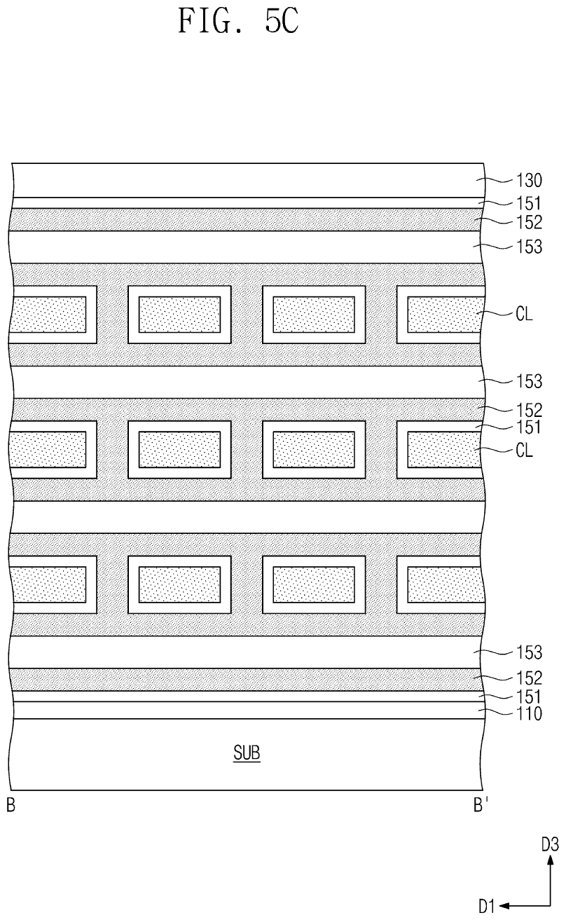

Referring to FIGS. 5A, 5B, and 5C, a preliminary gate dielectric layer 151, a preliminary dielectric pattern 152, and a preliminary filling pattern 153 may be sequentially formed. The preliminary gate dielectric layer 151, the preliminary dielectric pattern 152, and the preliminary filling pattern 153 may be formed in the first and second trenches TR1 and TR2 and in empty spaces formed by removing the sacrificial layers 141 and the separation patterns 143. The preliminary gate dielectric layer 151 and the preliminary dielectric pattern 152 may be conformally formed. The preliminary dielectric pattern 152 may include a material having an etch selectivity with respect to the preliminary gate dielectric layer 151 and the preliminary filling pattern 153. For example, the preliminary dielectric pattern 152 may include nitride, and the preliminary gate dielectric layer 151 and the preliminary filling pattern 153 may include oxide. The preliminary gate dielectric layer 151 may be in contact with the channel patterns CL. The preliminary dielectric pattern 152 may be in contact with the preliminary gate dielectric layer 151 and the preliminary filling pattern 153.

Referring to FIGS. 6A, 6B, 6C, and 6D, the first trench TR1 may be opened. The first trench TR1 may be opened by removing a portion of each of the preliminary gate dielectric layer 151, the preliminary dielectric pattern 152, and the preliminary filling pattern 153 that fill the first trench TR1. A filling pattern 113 may be defined to refer to the preliminary filling pattern 153 whose portion is removed, that is, remaining portions of the preliminary filling pattern 153.

The first trench TRI may be opened to expose a first exposure surface 161 of the channel pattern CL. The first exposure surface 161 of the channel pattern CL may be a surface exposed by removing a portion of the preliminary gate dielectric layer 151. The term “exposed,” may be used to describe relationships between elements and/or certain intermediate processes in fabricating a completed semiconductor device, but may not necessarily require exposure of the particular region, layer, structure or other element in the context of the completed device.

The preliminary dielectric pattern 152 exposed through the first trench TRI may be selectively etched. The preliminary dielectric pattern 152 may be selectively etched to form first dielectric patterns 111. The preliminary dielectric pattern 152 may be divided into the first dielectric patterns 111.

A first dummy word line DW1, a second dummy word line DW2, word lines WO, and second dielectric patterns 112 may be formed in first spaces 154 formed by etching the preliminary dielectric pattern 152. The formation of the first dummy word line DW1, the second dummy word line DW2, the word lines WO, and the second dielectric patterns 112 may include forming the first dummy word line DW1, the second dummy word line DW2, and the word lines WO, and forming the second dielectric patterns 112 that cover the first dummy word line DW1, the second dummy word line DW2, and the word lines WO.

Referring to FIGS. 7A, 7B, 7C, 7D, 7E, and 7F, the preliminary gate dielectric layer 151 may be selectively etched through the first trench TR1. The preliminary gate dielectric layer 151 may be selectively etched to expose a second exposure surface 162 of the channel pattern CL. The second exposure surface 162 of the channel pattern CL may be a surface exposed by selectively etching the preliminary gate dielectric layer 151. The preliminary gate dielectric layer 151 may be selectively etched to form second spaces 155.

The channel pattern CL may be doped with impurities having a first conductivity type. The first conductivity type impurities may be doped into the channel pattern CL through the first exposure surface 161 and the second exposure surface 162 of the channel pattern CL. A portion doped with the first conductivity type impurities may be defined as a first source/drain region SD1 of the channel pattern CL.

Referring to FIGS. 8A, 8B, and 8C, the channel pattern CL may be doped with impurities having a second conductivity type. The second conductivity type impurities may be doped into the channel pattern CL through the first exposure surface 161 and the second exposure surface 162 of the channel pattern CL. The second conductivity type impurities may be doped to define a first impurity region IR1 and a second impurity region IR2. The first impurity region IR1 may be a region doped with only the first conductivity type impurities, and the second impurity region IR2 may be a region doped with the first conductivity type impurities and the second conductivity type impurities. A concentration of the second conductivity type impurities in the second impurity region IR2 may be greater than that of the first conductivity type impurities in the second impurity region IR2. The first impurity region IR1 may have the first conductivity type, and the second impurity region IR2 may have the second conductivity type.

The second impurity region IR2 may include a side portion 163 adjacent to the first trench TR1. The side portion 163 of the second impurity region IR2 may be disposed between the first impurity region IR1 and the first trench TR1. A distance in the second direction D2 between the first trench TR1 and the side portion 163 of the second impurity region IR2 may be less than a distance in the second direction D2 between the first trench TRI and the first impurity region IR1.

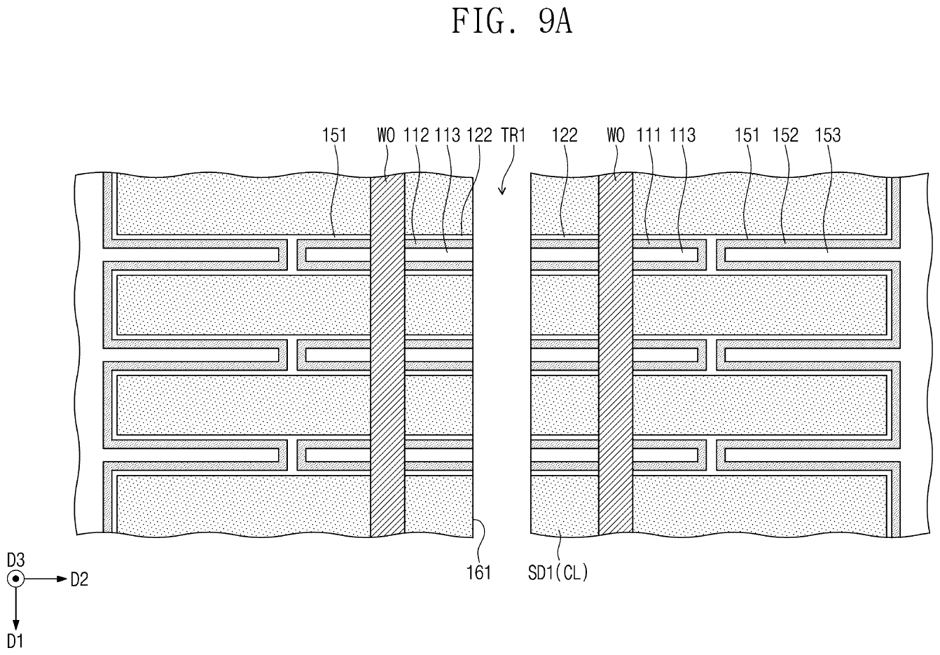

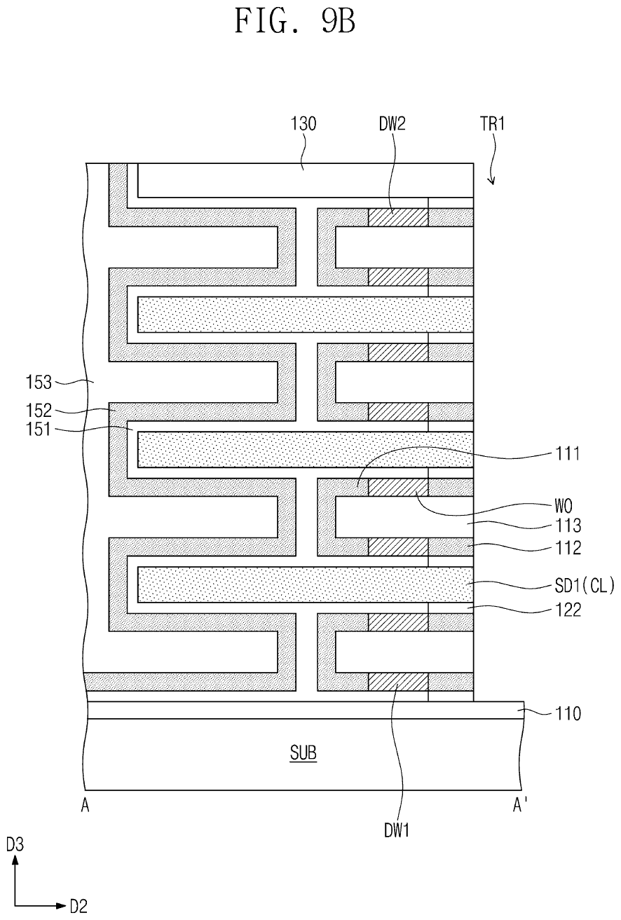

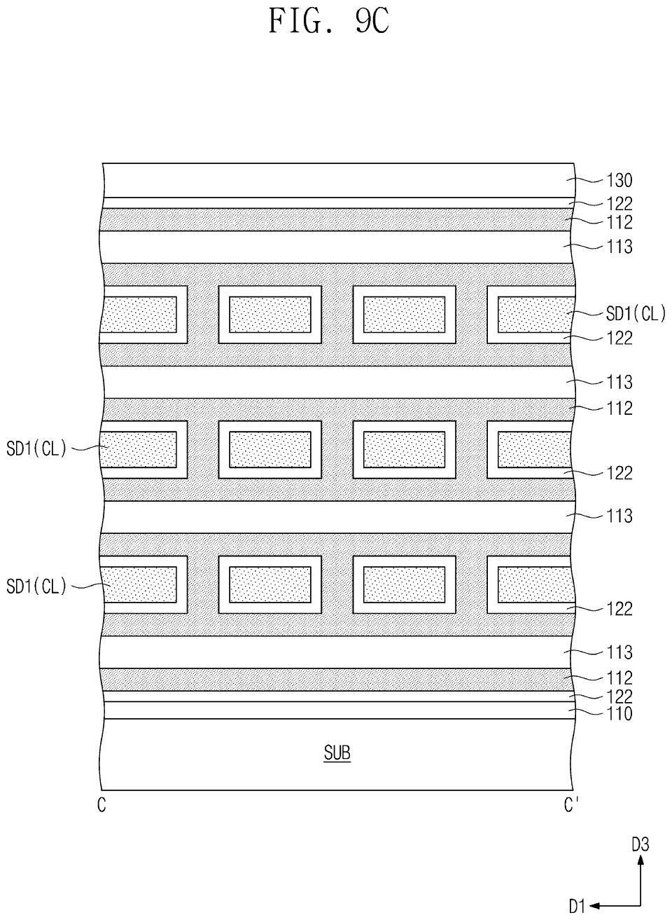

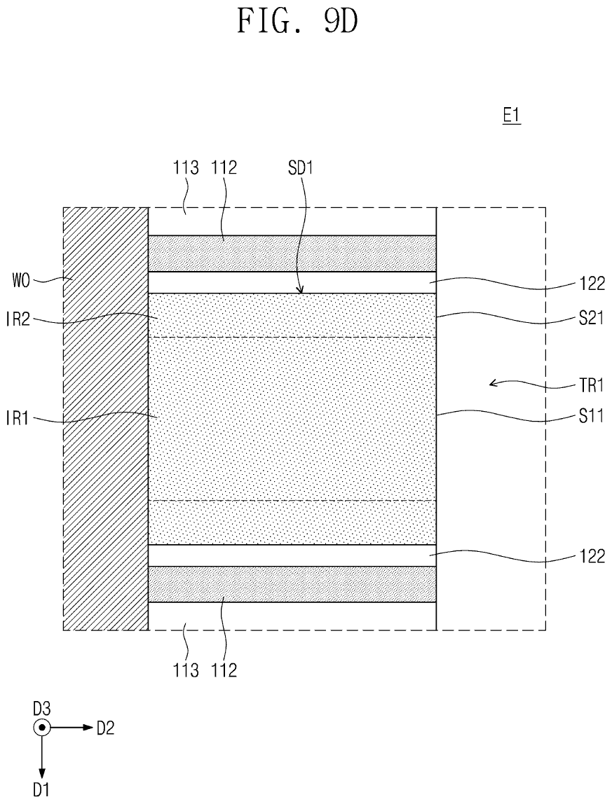

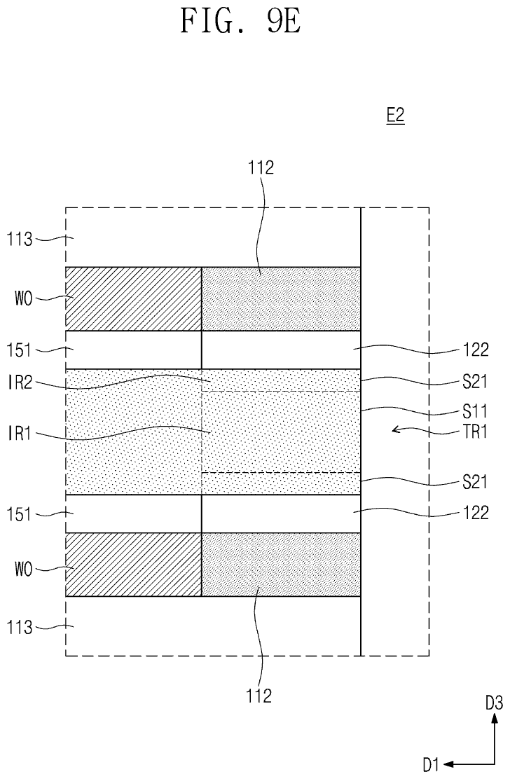

Referring to FIGS. 9A, 9B, 9C, 9D, and 9E, capping dielectric layers 122 may be formed in second spaces 155. The side portion 163 of the second impurity region IR2 may be removed. The removal of the side portion 163 of the second impurity region IR2 may expose a first surface S11 of the first impurity region IR1. The removal of the side portion 163 of the second impurity region IR2 may form a surface S21 of the second impurity region IR2. The first surface S11 of the first impurity region IR1 and the surface S21 of the second impurity region IR2 may be exposed through the first trench TR1.

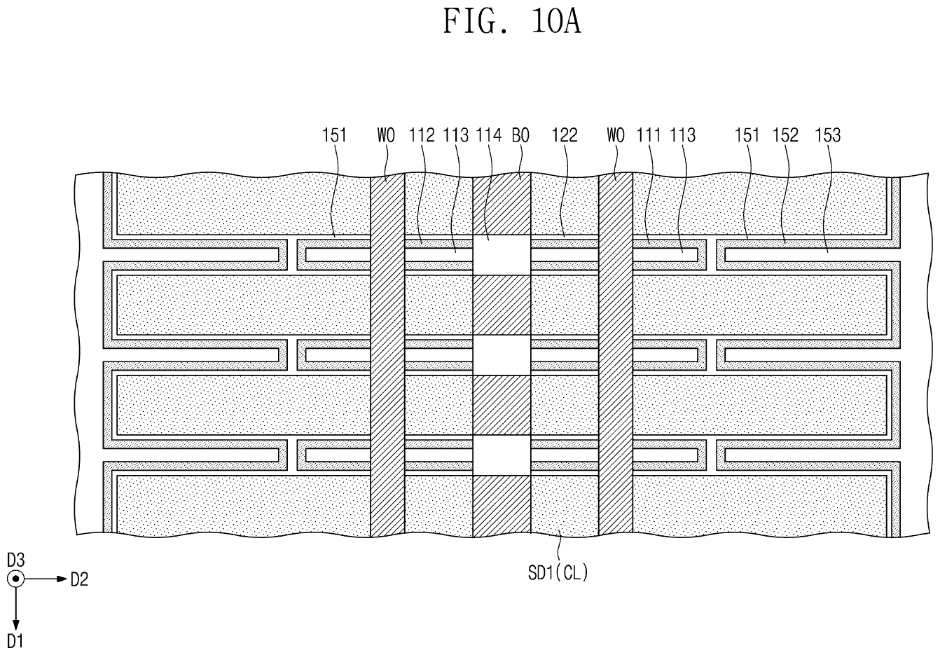

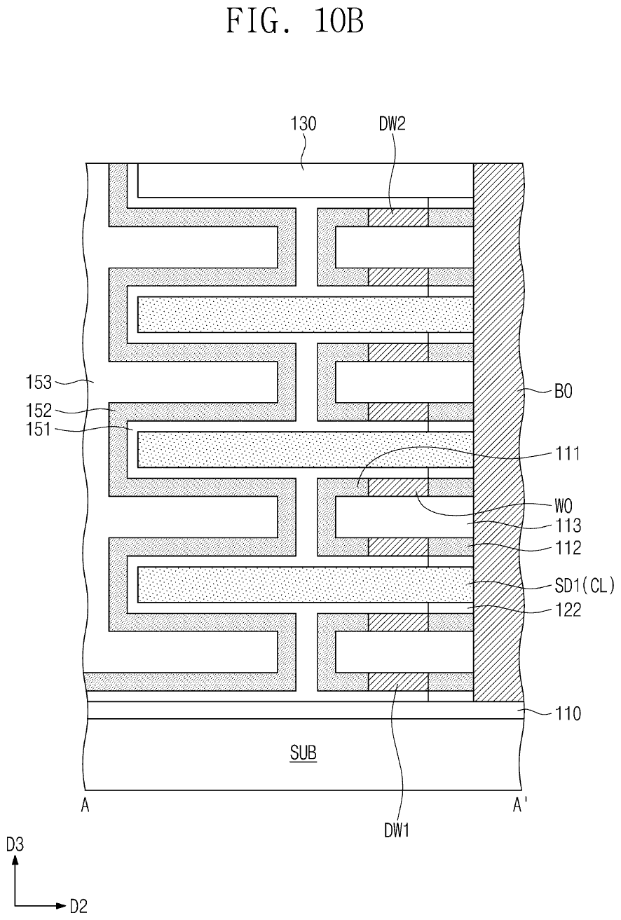

Referring to FIGS. 10A and 10B, bit lines BO and intervening patterns 114 may be formed. The bit lines BO and the intervening patterns 114 may be formed in the first trench TR1.

Referring to FIGS. 2A to 2G, the second trenches (see TR2 of FIGS. 4A and 4B) may be opened. A portion of the preliminary gate dielectric layer 151, the preliminary dielectric pattern 152, and the preliminary filling pattern 153 may be removed through the second trench TR2. A portion of the preliminary gate dielectric layer 151 may be removed through the second trench TR2, thereby forming a gate dielectric layer 121.

A portion of the preliminary gate dielectric layer 151, the preliminary dielectric pattern 152, and the preliminary filling pattern 153 may be removed to form a third space. A data storage structure DS may be formed in the third space.

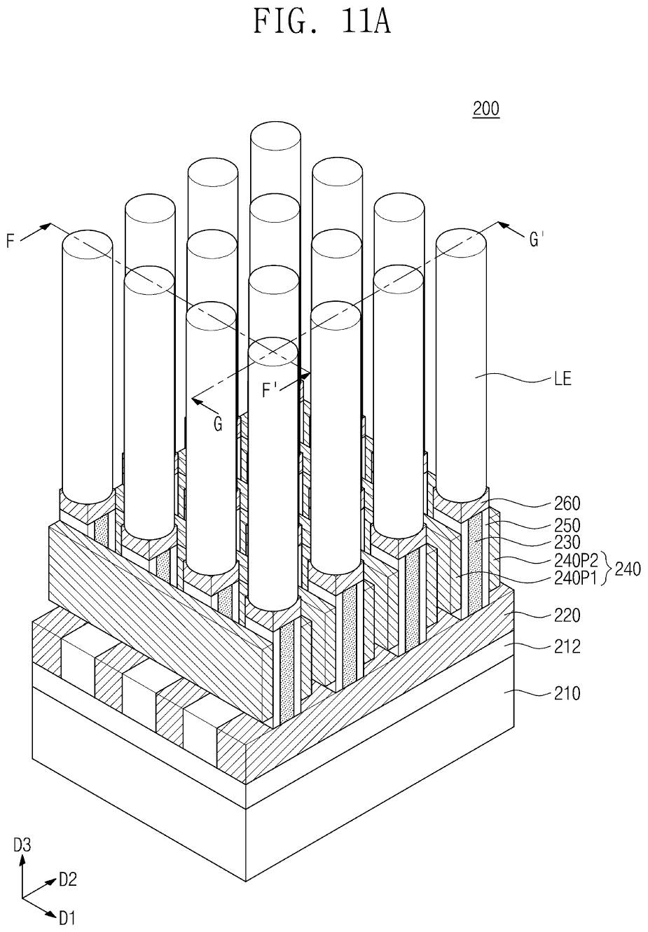

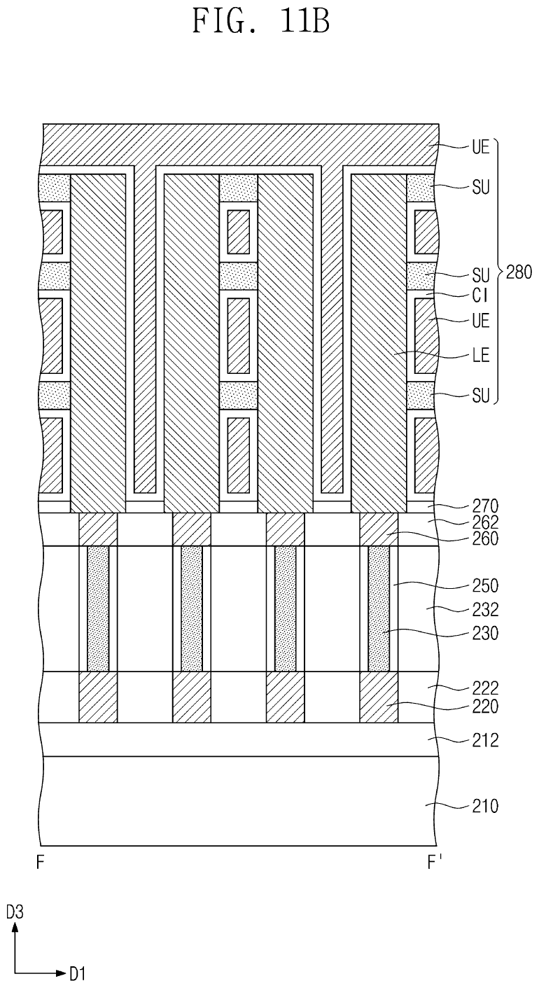

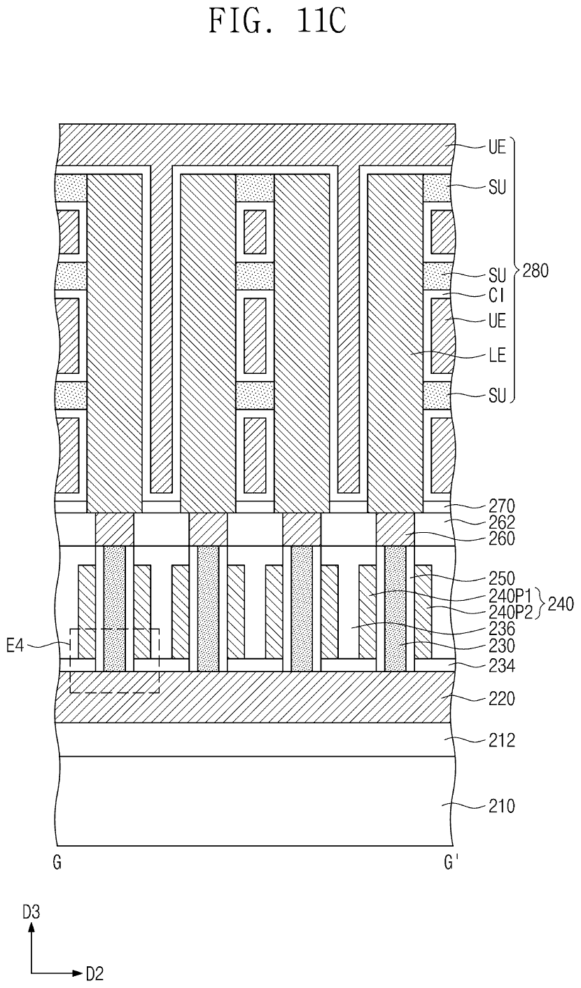

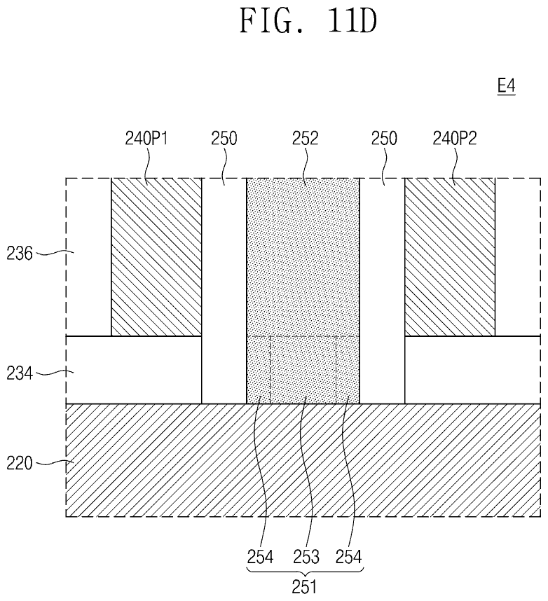

FIG. 11A illustrates a perspective view showing a semiconductor device according to some embodiments. FIG. 11B illustrates a cross-sectional view taken along line F-F′ of FIG. 11A. FIG. 11C illustrates a cross-sectional view taken along line G-G′ of FIG. 11A. FIG. 11D illustrates an enlarged view showing section E4 of FIG. 11C.

Referring to FIGS. 11A, 11B, 11C, and 11D, a semiconductor device 200 may include a substrate 210, a bit line 220, a channel pattern 230, a word line structure 240, a gate dielectric layer 250, and a data storage structure 280. The semiconductor device 200 may be a memory device including a vertical channel transistor (VCT). The vertical channel structure may indicate a structure where a channel length of the channel pattern 230 extends along a vertical direction (e.g., D3) from the substrate 210.

A lower dielectric layer 212 may be disposed on the substrate 210, and the lower dielectric layer 212 may be provided thereon with a plurality of bit lines 220 that are spaced apart from each other in a first direction D1 and extend in a second direction D2. The lower dielectric layer 212 may be provided thereon with a plurality of first dielectric structures 222 disposed to fill spaces between the plurality of bit lines 220. The plurality of first dielectric structures 222 may extend in the second direction D2, and may have their top surfaces located at the same level as (i.e., substantially coplanar with) that of top surfaces of the plurality of bit lines 220, relative to the substrate 210.

In some embodiments, the plurality of bit lines 220 may include doped polysilicon, metal, conductive metal nitride, conductive metal silicide, conductive metal oxide, or a combination thereof. For example, the plurality of bit lines 220 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof, but the present inventive concepts are not limited thereto. The plurality of bit lines 220 may include a single or multiple layer of materials mentioned above. In some embodiments, the plurality of bit lines 220 may include a two-dimensional semiconductor material, such as graphene, carbon nano-tube, or a combination thereof.

The channel pattern 230 may be disposed spaced apart in the first direction D1 and the second direction D2 to achieve an arrangement in a matrix shape on the plurality of bit lines 220. The channel pattern 230 may have a first width in the first direction D1 and a first height in the third direction D3, and the first height may be greater than the first width. For example, the first height may be about two to ten times the first width, but the present inventive concepts are not limited thereto. A bottom portion of the channel pattern 230 may serve as a first source/drain region 251, an upper portion of the channel pattern 230 may serve as a second source/drain region, and a portion of the channel pattern 230 between the first source/drain region 251 and the second source/drain region may serve as a channel region 252.

In some embodiments, the channel pattern 230 may include an oxide semiconductor, and the oxide semiconductor may include, for example, In Ga_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O, or a combination thereof. The channel pattern 230 may include a single or multiple layer of an oxide semiconductor. In some embodiments, the channel pattern 230 may have bandgap energy greater than that of silicon. For example, the channel pattern 230 may have bandgap energy of about 1.5 eV to about 5.6 eV. For example, the channel pattern 230 may have optimum channel performance when its bandgap energy ranges from about 2.0 eV to about 4.0 eV. For example, the channel pattern 230 may be polycrystalline or amorphous, but the present inventive concepts are not limited thereto. In some embodiments, the channel pattern 230 may include a two-dimensional semiconductor material, such as graphene, carbon nano-tube, or a combination thereof.

The word line structure 240 may extend in the first direction D1 on opposite sidewalls of the channel pattern 230. The word line structure 240 may include a first word line 240P1 directed toward a first sidewall and a second word line 240P2 directed toward a second sidewall of the channel pattern 230 opposite to the first sidewall of the channel pattern 230. As one channel pattern 230 is disposed between the first word line 240P1 and the second word line 240P2, the semiconductor device 200 may have a dual gate transistor structure. The present inventive concepts, however, are not limited thereto, and a single gate transistor structure may be achieved in which the second word line 240P2 is omitted and only the first word line 240P1 is formed to face the first sidewall of the channel pattern 230.

The word line structure 240 may include doped polysilicon, metal, conductive metal nitride, conductive metal silicide, conductive metal oxide, or a combination thereof. For example, the word line structure 240 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof, but the present inventive concepts are not limited thereto.

The gate dielectric layer 250 may be interposed between the channel pattern 230 and the word line structure 240, while surrounding a sidewall of the channel pattern 230. For example, an overall sidewall of the channel pattern 230 may be surrounded by the gate dielectric layer 250, and a portion of a sidewall of the word line structure 240 may be in contact with the gate dielectric layer 250. In some embodiments, the gate dielectric layer 250 may extend in an extension direction of the word line structure 240, and among sidewalls of the channel pattern 230, only two sidewalls directed toward the word line structure 240 may be in contact with the gate dielectric layer 250.

In some embodiments, the gate dielectric layer 250 may be formed of a silicon oxide layer, a silicon oxynitride layer, a high-k dielectric layer whose dielectric constant is greater than that of a silicon oxide layer, or a combination thereof. The high-k dielectric layer may be formed of metal oxide or metal oxynitride. For example, the high-k dielectric layer possibly used as the gate dielectric layer 250 may be formed of HfO₂, HfSiO, HfSiON, HfTaO, HfTIO, HfZrO, ZrO₂, Al₂O₃, or any combination thereof, but the present inventive concepts are not limited thereto.

A plurality of second dielectric structures 232 may extend along the second direction D2 on the plurality of first dielectric structures 222, and the channel pattern 230 may be disposed between two neighboring ones among the plurality of second dielectric structures 232. In addition, between two neighboring second dielectric structures 232, a first buried layer 234 and a second buried layer 236 (which may also be dielectric patterns) may be disposed in a space between two neighboring channel patterns 230. The first buried layer 234 may be disposed on a bottom portion of the space between two neighboring channel patterns 230, and on the first buried layer 234, the second buried layer 236 may be formed to fill an unoccupied portion of the space between two neighboring channel patterns 230. A top surface of the second buried layer 236 may be located at the same level as (i.e., substantially coplanar with) that of a top surface of the channel pattern 230 relative to the substrate 210, and the second buried layer 236 may cover a top surface of the word line structure 240. Alternatively, the plurality of second dielectric structures 232 and the plurality of first dielectric structures 222 may be formed of a continuous material layer, or the second buried layer 236 and the first buried layer 234 may be formed of a continuous material layer.

A capacitor contact structure 260 may be disposed on the channel pattern 230. The capacitor contact structure 260 may be disposed to vertically overlap the channel pattern 230 in the third direction D3, and may be disposed spaced apart in the first direction D1 and the second direction D2 to achieve an arrangement in a matrix shape. The capacitor contact structure 260 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof, but the present inventive concepts are not limited thereto. An upper dielectric layer 262 may surround a sidewall of the capacitor contact structure 260 on the plurality of second dielectric structures 232 and the second buried layer 236.

An etch stop layer 270 may be disposed on the upper dielectric layer 262, and a data storage structure 280 may be disposed on the etch stop layer 270. The data storage structure 280 may include a lower electrode LE, a capacitor dielectric layer CI, an upper electrode UE, and a support SU.

The first source/drain region 251 of the channel pattern 230 may include a first impurity region 253 and a second impurity region 254. The first impurity region 253 and the second impurity region 254 may be in contact with the bit line 220. The second impurity region 254 may surround the first impurity region 253.

The first impurity region 253 may have a first conductivity type. The second impurity region 254 may have a second conductivity type different from the first conductivity type. In some embodiments, the first conductivity type may be of n-type, and the second conductivity type may be of p-type. In some embodiments, the first conductivity type may be of p-type, and the second conductivity type may be of n-type. The first impurity region 253 may include first impurities of the first conductivity type. The second impurity region 254 may include first impurities of the first conductivity type and second impurities of the second conductivity type. A concentration of the second impurities in the second impurity region 254 may be greater than that of the first impurities of the second impurity region 254.

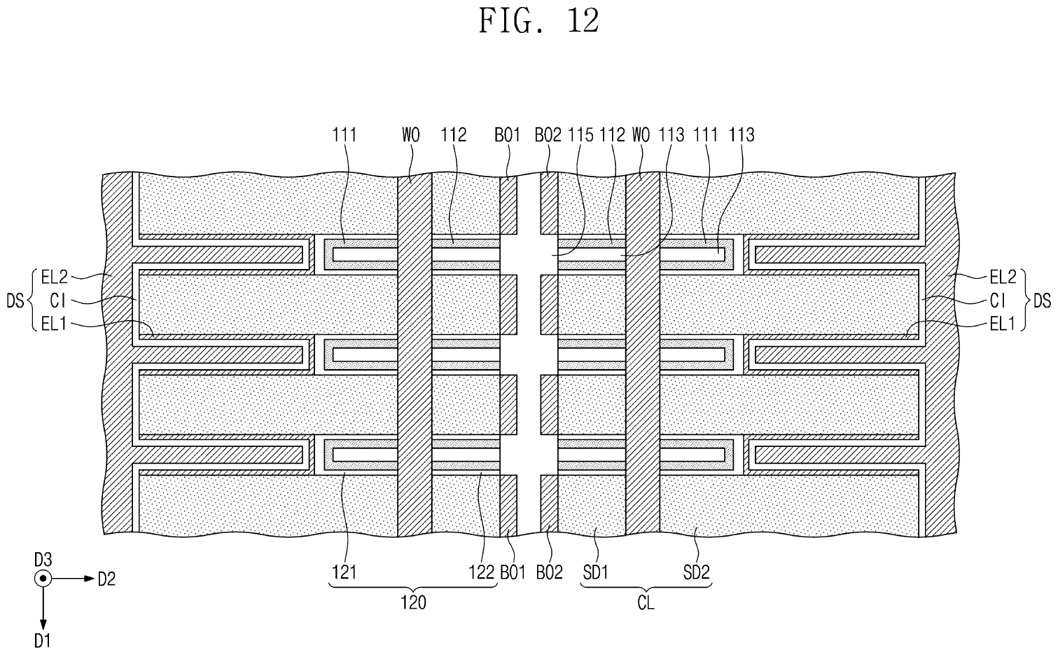

FIG. 12 illustrates a plan view showing a semiconductor device according to some embodiments. Except the following description, a semiconductor device according to FIG. 12 may be similar to the semiconductor device according to FIGS. 2A to 2G.

Referring to FIG. 12, the semiconductor device may include first bit lines BO1 and second bit lines BO2. The first bit lines BO1 and the second bit lines BO2 may be disposed between channel patterns CL that are spaced apart from each other in a second direction D2. The first bit lines BO1 and the second bit lines BO2 may be disposed between word lines WO that are spaced apart from each other in the second direction D2. The first bit line BO1 and the second bit line BO2 may be spaced apart from each other in the second direction D2. The first bit lines BO1 may be arranged spaced apart from each other in a first direction D1. The second bit lines BO2 may be arranged spaced apart from each other in the first direction D1.

The channel patterns CL may be connected to only one side of the first bit line BO1. The channel patterns CL may be connected to only one side of the second bit line BO2.

An intervening dielectric layer 115 may be provided between the first and second bit lines BO1 and BO2. The intervening dielectric layer 115 may separate the first and second bit lines BO1 and BO2 from each other. The first and second bit lines BO1 and BO2 may be disposed on opposite sides of the intervening dielectric layer 115. The intervening dielectric layer 115 may include a dielectric material. In some embodiments, the intervening dielectric layer 115 may be a multiple layer including a plurality of dielectric layers.

A semiconductor device according to some embodiments of the present inventive concepts may reduce or prevent a floating body effect to improve electrical properties of the semiconductor device.

Although the present invention has been described in connection with some embodiments of the present inventive concepts illustrated in the accompanying drawings, it will be understood to those skilled in the art that various changes and modifications may be made without departing from the present inventive concepts. It will be apparent to those skilled in the art that various substitution, modifications, and changes may be thereto without departing from the scope of the inventive concepts. Moreover, two or more embodiments of the present inventive concepts may be combined with each other.

What is claimed is:

1. A semiconductor device, comprising:
a bit line;
a data storage structure;
a word line between the bit line and the data storage structure;
a dielectric pattern between the word line and the bit line; and
a channel pattern that extends between the bit line and the data storage structure,
wherein the channel pattern comprises:
a channel region having the word line thereon;
a first impurity region of a first conductivity type; and
a second impurity region of a second conductivity type different from the first conductivity type,
wherein the first and second impurity regions are between the channel region and the bit line, and
wherein a distance between the first impurity region and the dielectric pattern is greater than a distance between the second impurity region and the dielectric pattern.

2. The semiconductor device of claim 1, wherein the first and second impurity regions are in contact with the bit line.

3. The semiconductor device of claim 1, further comprising:
a gate dielectric structure between the channel pattern and the word line,
wherein the second impurity region is in contact with the gate dielectric structure, and
wherein the first impurity region is spaced apart from the gate dielectric structure.

4. The semiconductor device of claim 3, wherein the second impurity region is between the first impurity region and the gate dielectric structure.

5. The semiconductor device of claim 1, wherein the second impurity region at least partially surrounds the first impurity region.

6. The semiconductor device of claim 1, wherein the first impurity region comprises:
a top boundary;
a bottom boundary;
a first boundary that extends between the top boundary and the bottom boundary; and
a second boundary opposite to the first boundary, and
wherein the second impurity region comprises:
a first portion in contact with the top boundary of the first impurity region;
a second portion in contact with the bottom boundary of the first impurity region;
a third portion in contact with the first boundary of the first impurity region; and
a fourth portion in contact with the second boundary of the first impurity region.

7. The semiconductor device of claim 1, wherein
the channel pattern comprises a plurality of channel patterns that are spaced apart from and overlap each other in a first direction, and
the bit line extends in the first direction to contact the first and second impurity regions of the plurality of channel patterns.

8. The semiconductor device of claim 1, wherein
the first impurity region includes a first impurity of the first conductivity type,
the second impurity region includes the first impurity of the first conductivity type and a second impurity of the second conductivity type, and
a concentration of the first impurity in the second impurity region is less than a concentration of the second impurity in the second impurity region.

9. A semiconductor device, comprising:
a bit line;
a data storage structure;
a word line between the bit line and the data storage structure; and
a channel pattern that extends between the bit line and the data storage structure,
wherein the channel pattern comprises:
a first impurity region of a first conductivity type; and
a second impurity region of a second conductivity type different from the first conductivity type, and
wherein the first and second impurity regions are in contact with the bit line.

10. The semiconductor device of claim 9, wherein
the first conductivity type is n-type, and
the second conductivity type is p-type.

11. The semiconductor device of claim 10, wherein
the second impurity region includes a p-type impurity and an n-type impurity, and
a concentration of the p-type impurity in the second impurity region is greater than a concentration of the n-type impurity in the second impurity region.

12. The semiconductor device of claim 9, wherein
the channel pattern comprises a plurality of channel patterns, and
the plurality of channel patterns extend between the bit line and the data storage structure.

13. The semiconductor device of claim 9, wherein the channel pattern comprises a channel region having the word line thereon, and wherein the first impurity region and the second impurity region are between the channel region and the bit line.

14. The semiconductor device of claim 9, wherein
the first impurity region has a first boundary in contact with the bit line,
the second impurity region has a second boundary in contact with the bit line, and
the first boundary and the second boundary are substantially coplanar with each other.

15. The semiconductor device of claim 14, wherein the second impurity region at least partially surrounds the first impurity region such that, in cross-section, the first boundary is within the second boundary.

16. A semiconductor device, comprising:
a bit line;
a data storage structure;
a word line between the bit line and the data storage structure; and
a channel pattern that extends between the bit line and the data storage structure,
wherein the channel pattern comprises:
a channel region having the word line thereon;
a first source/drain region between the channel region and the bit line; and
a second source/drain region between the channel region and the data storage structure,
wherein the first source/drain region comprises:
a first impurity region of a first conductivity type; and
a second impurity region of a second conductivity type different from the first conductivity type,
wherein the first impurity region includes a first impurity of the first conductivity type,
wherein the second impurity region includes the first impurity of the first conductivity type and a second impurity of the second conductivity type, and
wherein a concentration of the second impurity in the second impurity region is greater than a concentration of the first impurity in the second impurity region.

17. The semiconductor device of claim 16, wherein the first impurity region and the second impurity region are in contact with the bit line.

18. The semiconductor device of claim 17, wherein
the first impurity region has a boundary in contact with the bit line,
the second impurity region has a boundary in contact with the bit line, and
the boundary of the first impurity region and the boundary of the second impurity region are substantially coplanar with each other.

19. The semiconductor device of claim 16, wherein
the word line and the bit line are spaced apart from each other in a first direction, and
the first impurity region and the second impurity region each extend over an entirety of a length in the first direction between the channel region and the bit line.

20. The semiconductor device of claim 16, further comprising:
a gate dielectric structure between the channel pattern and the word line,
wherein the second impurity region is between the first impurity region and the gate dielectric structure, and
wherein a concentration of the second impurity in the second impurity region decreases in a direction toward the first impurity region.
